(19) United States
(12) Patent Application Publication
(10) Pub. No.: US 2008/0240479 A1
(43) Pub. Date: Oct. 2, 2008

(54) HYDROPHOBIC AND OLEOPHOBIC COATING AND METHOD FOR PREPARING THE SAME

(75) Inventors: Matthew R. Linford, Orem, UT (US); Gaurav Saini, Provo, UT (US)

Correspondence Address: HOLLAND & HART LLP, 60 E. South Temple, Suite 2000, P.O. Box 11583, Salt Lake City, UT, 84110, US

(73) Assignee: Sonic Innovations, Inc.

(21) Appl. No.: 11/866,897

(22) Filed: Oct. 3, 2007

Related U.S. Application Data
(60) Provisional application No. 60/849,233, filed on Oct. 3, 2006.

(51) Int. Cl. B05D 3/04; B05D 3/10; B05D 3/06; C23C 16/44; B32B 9/00; C04B 41/50; H04R 25/00

(52) U.S. Cl. 381/323; 427/333; 427/299; 427/535; 427/553; 427/255.23; 428/447; 106/287.1; 381/312; 381/322

(57) ABSTRACT

A hydrophobic and oleophobic coating, comprising an adhesion promoting layer formed from an adhesion promoting composition and a hydrophobic layer formed from a hydrophobic layer forming composition, is disclosed. The adhesion promoting composition may comprise an adhesion promoting compound having a functional linking group and at least one of a silane functional group and/or a germanium functional group. The hydrophobic layer forming composition may comprise a hydrophobic layer forming compound having a hydrophobic aliphatic group and at least one of a silane functional group and/or a germanium functional group. A method of forming the coating is also disclosed.

### CROSS REFERENCE TO RELATED APPLICATION

This application claims the priority benefit of U.S. Provisional Application No. 60/849,233, filed Oct. 3, 2006, the disclosure of which is incorporated, in its entirety, by this reference.

### BACKGROUND

Many polymer/plastic materials have desirable bulk properties such as low density, low cost, good strength, and ease of processing that have allowed them to become integral components of countless consumer goods and devices. However, many plastics that have ideal bulk properties for certain applications are lacking in their surface properties, such as, for example, abrasion resistance and wetting. As a result, it may be desirable to coat a polymer/plastic to modify its surface so that its favorable bulk properties can be exploited for various uses.

In many instances, various devices are designed to prevent water from entering interior portions of the devices in order to maintain proper functionality. Manufacturers often design devices to be used in environments where water or other liquid materials may come into contact with the devices and components of the devices. Devices and device components may have various protective coverings to protect interior portions of the devices and components. Often, the protective covering is made from multiple parts, resulting in various seams and openings that may expose interior portions to damage from liquids. Many devices also require small openings or interstices in the protective cover in order to allow air or other gases to flow freely between the interior and exterior of the device while preventing liquids from passing through the cover. For example, a battery used in powering an electronic device may be susceptible to damage from moisture, and may nonetheless require an external source of oxygen to operate. Additionally, devices may contain a liquid material that is intended to be contained within the device for an extended time until the liquid is dispensed. An ink jet cartridge, for example, often contains a liquid ink solution that is contained within the cartridge for extended periods.

### SUMMARY

According to at least one embodiment, a method may comprise depositing a first silane onto a surface, the first silane comprising a functional linking group and a silane group, and depositing a second silane onto the first silane, the second silane comprising a hydrophobic aliphatic group and a silane group.

In certain embodiments, a composition of matter may comprise the reaction product of a substrate comprising a hydroxyl group, a first silane comprising a functional linking group and a silane group, and a second silane comprising a hydrophobic aliphatic group and a silane group.

In various embodiments, a coating composition may comprise a first silane bonded to the surface, the first silane comprising a silane group, and a second silane bonded to the first silane by a siloxane linkage, the second si ane comprising a hydrophobic aliphatic group.

In certain embodiments, an article may comprise a first portion having a surface, a first silane bonded to the surface of the first portion, the first silane comprising a silane group, and a second silane bonded to the first silane by a siloxane linkage, the second silane comprising a hydrophobic aliphatic group.

In additional embodiments, a hearing aid device may comprise a first component, the first component having a surface portion, a coating composition bonded to the surface portion of the first component, the coating composition comprising an adhesion layer bonded to the surface portion of the first component, and a hydrophobic layer bonded to the adhesion layer.

In at least one embodiment, a method may comprise depositing an adhesion promoting compound onto a surface, the adhesion promoting compound comprising a functional linking group and at least one of a silane functional group and a germanium functional group. The method may also comprise depositing a hydrophobic layer forming compound onto the adhesion promoting compound, the hydrophobic layer forming compound comprising a hydrophobic aliphatic group and at least one of a silane functional group and a germanium functional group.

In various embodiments, a composition of matter may comprise the reaction product of a substrate comprising a hydroxyl group, an adhesion promoting composition comprising an adhesion promoting compound, the adhesion promoting compound comprising a functional linking group and at least one of a silane functional group and a germanium functional group, and a hydrophobic layer forming composition comprising a hydrophobic layer forming compound, the hydrophobic layer forming compound comprising a hydrophobic aliphatic group and at least one of a silane functional group and a germanium functional group.

Features from any of the above-mentioned embodiments may be used in combination with one another in accordance with the general principles described herein. These and other embodiments, features, and advantages will be more fully understood upon reading the following detailed description in conjunction with the accompanying drawings and claims.

### BRIEF DESCRIPTION OF THE DRAWINGS

The accompanying drawings illustrate a number of exemplary embodiments and are a part of the specification. Together with the following description, these drawings demonstrate and explain various principles of the instant disclosure.

FIG. 1 is a cross-sectional view of a portion of an exemplary article comprising a coating according to at least one embodiment;

FIG. 2 is a flow diagram of an exemplary method for forming a coating on a surface according to an additional embodiment;

FIG. 3 is a flow diagram of an exemplary method for forming a coating on a surface according to an additional embodiment;

FIG. 4 is a flow diagram of an exemplary method for forming a coating on a surface according to an additional embodiment;

FIG. 5 is a flow diagram of an exemplary method for forming a coating on a surface according to an additional embodiment;

FIG. 6 is a flow diagram of an exemplary method for forming a coating on a surface according to an additional embodiment;

FIG. 7 is a flow diagram of an exemplary method for forming a coating on a surface according an additional embodiment;

FIG. 8 is a flow diagram of an exemplary method for forming a coating on a surface according an additional embodiment;

FIG. 9 is a flow diagram of an exemplary method for forming a coating on a surface according an additional embodiment;

FIG. 10A is an exemplary hearing aid device on a portion of which a coating is formed according to an additional embodiment;

FIG. 10B is an exemplary hearing aid device on a portion of which a coating is formed according to an additional embodiment;

FIG. 10C is an exemplary hearing aid device on a portion of which a coating is formed according to an additional embodiment;

FIG. 10D is an exemplary hearing aid device on a portion of which a coating is formed according to an additional embodiment;

FIG. 11 is an exemplary silicon-based article on a portion of which a coating is formed according to an additional embodiment.

Throughout the drawings, identical reference characters and descriptions indicate similar, but not necessarily identical, elements. While the exemplary embodiments described herein are susceptible to various modifications and alternative forms, specific embodiments have been shown by way of example in the drawings and will be described in detail herein. However, the exemplary embodiments described herein are not intended to be limited to the particular forms disclosed. Rather, the instant disclosure covers all modifications, equivalents, and alternatives falling within the scope of the appended claims.

### DETAILED DESCRIPTION OF EXEMPLARY EMBODIMENTS

The silane compositions presented in the instant disclosure may be deposited on an article to provide the article with various properties. Methods of applying the compositions to various articles are also presented in the instant disclosure. The compositions and methods discussed herein may also provide various other features and advantages.

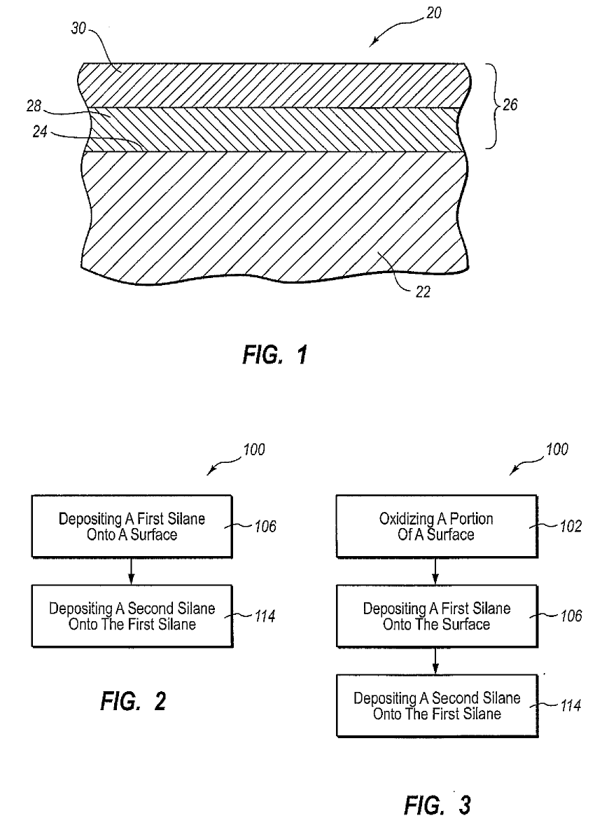

FIG. 1 is an exemplary article 20 comprising a substrate 22 and a coating 26. As illustrated in this figure, substrate 22 may comprise a surface 24. Additionally, coating 26 may comprise an adhesion promoting layer 28 and a hydrophobic layer 30. Article 20 may comprise any suitable article or device having a surface portion. Examples of article 20 may include, without limitation, electronic devices, silicon wafers, silicon chips, ink jet cartridges, plastic films, batteries, battery contacts, rechargeable batteries, mesh coverings, ear pieces, and components of the foregoing. Article 20 may also comprise surfaces formed in any shape, size, texture, or configuration, including, for example, planar surfaces, curved surfaces, rough surfaces, smooth surfaces, and/or irregular surfaces. Additionally, article 20 may include various hearing aid devices, components, and/or accessories, including, for example, shell components, covers, in-the-ear domes (e.g., for open car products), microphone covers (e.g., fabric mesh covers), volume controllers, switches, buttons, microphone ports, receiver ports, tubing, ear hooks, acoustic damping elements, battery doors, batteries, battery contacts, nozzles, DAI connectors, moisture and/or wax guards, face plate elements, ear molds (e.g., for standard ear molds and custom ear molds), and any other hearing aid device or component.

Substrate 22 may comprise any material or combination of materials suitable for deposition of a silane compound as described below. Examples of materials suitable for forming substrate 22 include, without limitation, polymer materials, metallic materials, composite materials, silicon-based materials, semiconducting materials, insulating materials, or a combination of the foregoing. Surface 24 of substrate 22 may comprise an external and/or internal portion of substrate 22 and/or article 20.

Coating 26 may be formed on portions of completed article assemblies, article sub-assemblies, individual articles, device components, and/or shell components. Coating 26 may have a substantially consistent thickness respective to surface 24. Alternatively, coating 26 may be applied to surface 24 intermittently and/or in a specific pattern. Additionally, coating 26 may be applied to surface 24 only on desired portions of surface 24, such as, for example, portions of surface 24 contacting or in close proximity to a seam, hole, interstice, or other opening defined in surface 24 or adjacent to surface 24. Coating 26 may provide surface 24 with various properties, including, for example, increased hydrophobicity, increased oleophobicity, increased abrasion resistance, increased protection from staining, and/or increased protection from discoloration. Coating 26 may additionally provide portions of surface 24 and/or substrate 22 with gas permeability while providing surface 24 with liquid impermeability. Additionally, coating 26 may comprise an ultra-thin transparent layer, enabling coating 26 to be formed on surface 24 with little to no impact on functionality or aesthetics of article 20.

Adhesion promoting layer 28 may be formed on surface 24. In certain embodiments, adhesion promoting layer 28 may be bonded to surface 24. Adhesion promoting layer 28 may act as an adhesion promoter to bond and secure additional compounds to substrate 24. Adhesion promoting layer 28 may comprise a first silane having at least two reactive groups. In addition, the first silane and/or the adhesion promoting layer 28 may comprise mixtures of various silane compounds. Adhesion promoting layer 28 may also comprise additional compounds in addition to the first silane. The additional compounds in adhesion promoting layer 28 may impart various desirable properties to adhesion promoting layer 28, such as, for example, microbial resistance, without preventing adhesion promoting layer 28 and/or the first silane from acting as an adhesion promoter.

In certain embodiments, adhesion promoting layer 28 may comprise a germanium based compound in addition to or in place of a silane compound (e.g. the first silane). Germanium based compounds may function as adhesion promoters in a manner similar to analogous silicon compounds. Accordingly, silicon compounds listed below as examples of the first silane may be substituted or replaced with an analogous germanium compound.

The first silane may be capable of forming polymers containing siloxane (Si—O—Si) linkages. In at least one embodiment, the first silane may comprise at least one of an isocyanate group, an acyl chloride group, an epoxide group, a glycidyl group, an amino group, a methyl ester group, an isothiocyanato group, a carboxyl group, an activated carboxyl group, an alkyl chloride group, an alkyl bromide group, an alkyl iodide group, a benzyl chloride group, a benzyl bromide group, a chlorosilane group (e.g., —SiCl₃), a methoxysilane group (e.g., —Si(OCH₃)₃), an ethoxysilane group (e.g., —Si(OCH₂CH₃)₃), and/or any other suitable reactive functional group, without limitation.

The first silane may also comprise at least one silane group. In an exemplary embodiment, the silane group on the first silane may be represented by formula (I):

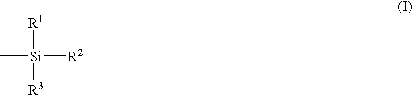

where R¹, R², and R³ may each be, independently, P, Cl, Br, I, H, OH, a methoxy group, an ethoxy group, an isopropoxy group, an alkoxy group, an acetoxy group, a methyl group, an alkyl group, a perfluoroalkyl group, a partially fluorinated alkyl group, a dimethylamino group, a dialkylamino group, an ethylamino group, a monoalkylamino group, an amino group, a phenyl group, or a methoxyethoxyethoxy group.

In at least one embodiment, the first silane may be represented by formula (II):

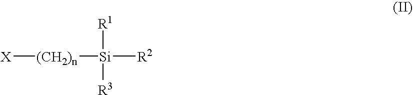

where X may be an isocyanate group, an acyl chloride group, an epoxide group, a glycidyl group, an amino group, a methyl ester group, an isothiocyanato group, a carboxyl group, an activated carboxyl group, an alkyl chloride group, an alkyl bromide group, an alkyl iodide group, a benzyl chloride group, a benzyl bromide group, a chlorosilane group (e.g., —SiCl₃), a methoxysilane group (e.g., —Si(OCH₃)₃), an ethoxysilane group (e.g., —Si(OCH₂CH₃)₃), and/or any other suitable reactive functional group, without limitation. In formula (II), n may be an integer from 0-32. In additional embodiments, n may be an integer from 1-18. In at least one embodiment, n may be an integer from 3-4. Additionally, in formula (II), R¹, R², and R³ may be as defined above for formula (I).

Representative examples of the first silane include, without limitation, 3-isocyanatopropyltriethoxysilane, 3-isocyanatopropyltrimethoxysilane, 4-isocyanatobutyltriethoxysilane, 4-isocyanatobutyltrimethoxysilane, 3-isocyanatopropyldimethylchlorosilane, (isocyanatomethyl)methyldimethoxysilane, 3-thiocyanatopropyltriethoxysilane, 3-aminopropyltriethoxysilane, 3-aminopropyltrimethoxysilane, 4-aminobutyltriethoxysilane, 4-aminobutyltrimethoxysilane, (aminoethylaminomethyl)phenethyl-trimethoxysilane, N-(2-Aminoethyl)-3-aminoisobutyl-methyldimethoxysilane, N-methylaminopropyltrimethoxysilane, N-methylaminopropyltriethoxysilane, N-methylaminopropylmethyldimethoxysilane, N-methylaminopropylmethyldiethoxysilane, N-ethylaminoisobuyltrimethoxysilane, (N,N-diethyl-3-aminopropyl)trimethoxysilane, (N,N-diethyl-3-aminopropyl)triethoxysilane, n-butylaminopropyltrimethoxysilane, 11-aminoundecyltriethoxysilane, 11-aminoundecyltrimethoxysilane, 3-aminopropylmethyldiethoxysilane, 3-aminopropylmethyldimethoxysilane, 3-aminopropyldimethylethoxysilane, 3-aminopropyldimethylmethoxysilane, 3-aminopropyltris(methoxyethoxyethoxy)silane, N-(2-aminoethyl)-3-aminopropyltrimethoxysilane, N-(2-amino ethyl)-3-aminopropyltri ethoxysilane, (amino ethylaminomethyl)phenethyltrimethoxysilane, (amino ethylaminomethyl)phenethyltriethoxysilane, N-(2-aminoethyl)-3-aminoisobutylmethyldimethoxysilane, N-(2-aminoethyl)-3-aminoisobutylmethyldiethoxysilane, N-(2-aminoethyl)-3-aminoisobutyldimethylmethoxysilane, N-(2-aminoethyl)-3-aminoisobutyldimethylethoxysilane, (3-glycidoxypropyl)trimethoxysilane, (3-glycidoxypropyl)triethoxysilane, (3-glycidoxypropyl)methyldimethoxysilane, (3-glycidoxypropyl)methyldiethoxysilane, (3-glycidoxypropyl)dimethylethoxysilane, (3-glycidoxybutyl)trimethoxysilane, (3-glycidoxybutyl)triethoxysilane, SiCl₄, Si(CH₃)Cl₃, Si(CH₃)₂Cl₂, Si(OCH₃)₄, Si(CH₃)(OCH₃)₃, Si(CH₃)₂(OCH₃)₂, Si(OCH₂CH₃)₄, Si(CH₃)(OCH₂CH₃)₃, Si(CH₃)₂(OCH₂CH₃)₂, Si(N(CH₃)₂)₄, SiH(N(CH₃)₂)₃, and Si(CH₃)(N(CH₃)₂)₃, SiCl(N(CH₃)₂)₃, Si(CH₃)H(N(CH₃)₂)₂.

Additional examples of the first silane that may be capable of binding to surface 24 through, for example, siloxane or other end group linkages, include, without limitation, bis(dimethylaminodimethylsilyl)ethane, bis(dimethylamino)vinylmethylsilane, 3-mercaptopropyltriethoxysilane, acetoxyethyltrimethoxysilane, bis(chloromethyl)dichlorosilane, bis(chloromethyl)methylchlorosilane, bis(dichlorosilyl)methane, bis(methyldichlorosilyl)ethane, bis(trichlorosilyl)hexane, bis(trichlorosilyl)methane, bis(trichlorosilyl)octane, 1,3-bis(trichlorosilyl)propane, bis(triethoxysilyl)ethane, 2-bromoethyltrichlorosilane, 1-chloroethyltrichlorosilane, hexachlorodisilane, methyltrichlorosilane, hexadecyltrichlorosilane, tetrabromosilane, trichloromethyltrichlorosilane, tris(trichlorosilylethyl)methylsilane, and tris(p-trichlorosilylpropylphenyl)amine, bis(methyl dichloro silyl)butane.

Hydrophobic layer 30 may be formed on adhesion promoting layer 28. In certain embodiments, hydrophobic layer 30 may be bonded to adhesion promoting layer 28. The hydrophobic layer 30 may act as a hydrophobic and/or oleophobic layer. Additionally, the second silane may act as a hydrophobic and/or oleophobic compound. Hydrophobic layer 30 may comprise a second silane having at least one perfluorinated aliphatic group and at least one silane group. Hydrophobic layer 30 may also comprise additional compounds in addition to the second silane. The additional compounds in hydrophobic layer 30 may impart various desirable properties to hydrophobic layer 30, such as, for example, microbial resistance, without preventing hydrophobic layer 30 and/or the second silane from acting as a hydrophobic and/or oleophobic layer or compound.

In order to impart hydrophobic characteristics to coating 26, the second silane may comprise long alkyl chains, partially fluorinated alkyl chains, and/or alkyl chains that have regions that are perfluorinated, any of which may be straight or branched. For example, the second silane may comprise alkyl chains having the general formulas CF₃(CF₂)ₙ(CH₂)ₘSiR¹R²R³ and/or CF₂H(CF₂)ₙ(CH₂)ₘSiR¹R²R³, where n and m are integers (n≧0, and m≧0). In addition, the second silane and/or the hydrophobic layer 30 may comprise mixtures of alkyl, perfluoroalkyl, or partially fluorinated alkyl chains.

The second silane may be capable of bonding to the first silane through, for example, a siloxane (Si—O—Si) linkage. Additionally, the second silane may be capable of forming polymers containing siloxane linkages. In an exemplary embodiment, the silane group on the second silane may be represented by formula (III):

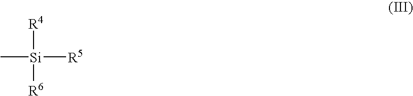

where R⁴, R⁵, and R⁶ may each be, independently, F, Cl, Br, I, H, OH, a methoxy group, an ethoxy group, an isopropoxy group, an alkoxy group, an acetoxy group, a methyl group, an alkyl group, a perfluoroalkyl group, a partially fluorinated alkyl group, a dimethylamino group, a dialkylamino group, an ethylamino group, a monoalkylamino group, an amino group, a phenyl group, or a methoxyethoxyethoxy group.

In at least one embodiment, the second silane may be represented by formula (IV):

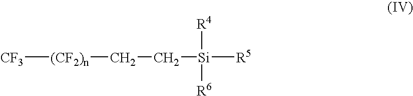

where n may be an integer from 0-32, and R⁴, R⁵, and R⁶ may be as defined above for formula (III). In additional embodiments, n may be an integer from 1-16. In at least one embodiment, n may be an integer from 5-9.

Representative examples of the second silane include, without limitation, (tridecafluoro-1,1,2,2-tetrahydrooctyl)trichlorosilane, (tridecafluoro-1,1,2,2-tetrahydrooctyl)methyldichlorosilane, (tridecafluoro-1,1,2,2-tetrahydrooctyl)trimethoxysilane, (tridecafluoro-1,1,2,2-tetrahydrooctyl)triethoxysilane, (tris(tridecafluoro 1,1,2,2-tetrahydrooctyl)dimethylsiloxy)chlorosilane, (heptadecafluoro-1,1,2,2-tetrahydrodecyl)trichlorosilane, triethoxy(1H,1H,2H,2H-perfluorooctyl)silane, (heptadecafluoro-1,1,2,2-tetrahydrodecyl)triethoxysilane, (heptadecafluoro-1,1,2,2-tetrahydrodecyl)trimethoxysilane, (heptadecafluoro-1,1,2,2-tetrahydrodecyl)methyldichlorosilane, (heptadecafluoro-1,1,2,2-tetrahydrodecyl)dimethylchlorosilane, perfluorododecyl-1H,1H,2H,2H-triethoxysilane-perfluorotetradecyl-1H,1H,2H,2H-triethoxysilane mixture, 1,8-bis(trichlorosilylethyl)hexadecylfluorooctane, n-octadecyldimethylchlorosilane, n-octadecyldimethylmethoxysilane, n-octadecylmethoxydichlorosilane, n-octadecylmethyldichlorosilane, n-octadecylmethoxydichlorosilane, n-octadecylmethyldiethoxysilane, n-octadecyltrichlorosilane, n-octadecyltriethoxysilane, n-octadecyltrimethoxysilane, n-octadecyldimethyl(dimethylamino)silane, n-triacontyldimethylchlorosilane, n-triacontyltrichlorosilane, n-hexadecyltrichlorosilane, n-hexadecyltrimethoxysilane, n-hexadecyltriethoxysilane, n-dodecyltrichlorosilane, n-dodecyltrimethoxysilane, n-dodecyltriethoxysilane, n-dodecylmethyldichlorosilane, n-octyltrichlorosilane, n-octyltrimethoxysilane, n-octyltriethoxysilane, n-octylmethyldichlorosilane, and n-octyldimethylchliorosilane. The second silane may also include compounds according to the general formula CH₃(CH₂)ₙCHRCH₂SiCl₃, where R═CH₃(CH₂)ₘ, and n and m are integers (n≧0, and m≧0). The second silane may also include compounds according to the general formula CH₃(CH₂)ₙCHRSiCl₃, where R═CH₃(CH₂)ₘ, and n and m are integers (n≧0, and m≧0). The second silane may also include compounds according to the general formula CH₃(CH₂)ₙCHRSi(OCH₃)₃, where R═CH₃(CH₂)ₘ, and n and m are integers (n≧0, and m≧0).

In certain embodiments, adhesion promoting layer 28 may comprise a germanium compound in addition to or in place of a silane compound. Germanium compounds may function as hydrophobic and/or oleophobic compositions in a manner similar to analogous silicon compounds. Accordingly, silicon compounds listed above as examples of the first silane may be substituted with analogous germanium compounds, in which the Si atom is replaced with a Ge atom.

In at least one embodiment, the adhesion promoting layer 28 may comprise a germanium compound that acts as an adhesion promoter. The germanium compound in the adhesion promoting layer 28 may comprise at least one of an isocyanate group, an acyl chloride group, an epoxide group, a glycidyl group, an amino group, a methyl ester group, an isothiocyanato group, a carboxyl group, an activated carboxyl group, an alkyl chloride group, an alkyl bromide group, an alkyl iodide group, a benzyl chloride group, a benzyl bromide group, a chlorosilane group (e.g., —SiCl₃), a methoxysilane group (e.g., —Si(OCH₃)₃), an ethoxysilane group (e.g., —Si(OCH₂CH₃)₃), and/or any other suitable reactive functional group, without limitation. The germanium compound in the adhesion promoting layer 28 may also comprise at least one germanium group. In an exemplary embodiment, the germanium group on the germanium compound in the adhesion promoting layer 28 may be represented by formula (V):

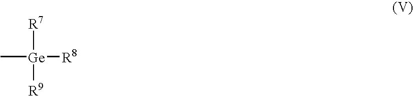

where R⁷, R⁸, and R⁹ may each be, independently, F, Cl, Br, I, H, OH, a methoxy group, an ethoxy group, an isopropoxy group, an alkoxy group, an acetoxy group, a methyl group, an alkyl group, a perfluoroalkyl group, a partially fluorinated alkyl group, a dimethylamino group, a dialkylamino group, an ethylamino group, a monoalkylamino group, an amino group, a phenyl group, or a methoxyethoxyethoxy group.

In at least one embodiment, the germanium compound in the adhesion promoting layer 28 may be represented by formula (VI):

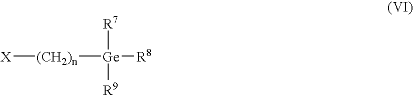

where X may be an isocyanate group, an acyl chloride group, an epoxide group, a glycidyl group, an amino group, a methyl ester group, an isothiocyanato group, a carboxyl group, an activated carboxyl group, an alkyl chloride group, an alkyl bromide group, an alkyl iodide group, a benzyl chloride group, a benzyl bromide group, a chlorosilane group (e.g., —SiCl₃), a methoxysilane group (e.g., —Si(OCH₃)₃), an ethoxysilane group (e.g., —Si(OCH₂CH₃)₃), and/or any other suitable reactive functional group, without limitation. In formula (VI), n may be an integer from 0-32. In additional embodiments, n may be an integer from 1-18. In at least one embodiment, n may be an integer from 3-4. Additionally, in formula (VI), R⁷, R⁸, and R⁹ may be as defined above for formula (V).

In certain embodiments, hydrophobic layer 30 may comprise a germanium compound in addition to or in place of a silane compound. Germanium compounds may function as hydrophobic and/or oleophobic compositions in a manner similar to analogous silicon compounds. Accordingly, silicon compounds listed above as examples of the second silane may be substituted with analogous germanium compounds, in which the Si atom is replaced with a Ge atom.

The germanium compound in hydrophobic layer 30 may be capable of bonding to a silane (e.g., the first silane) or a germanium compound through, for example, a siloxane (Si—O—Si) linkage, a Ge—O—Si linkage, and/or a Ge—O—Ge linkage, The germanium compound in adhesion promoting layer 28 may also be capable of bonding to a silane (e.g., the first silane) or a germanium compound through, for example, a siloxane linkage, Ge—O—Si linkage, and/or a Ge—O—Ge linkage. Additionally, the germanium compound in hydrophobic layer 30 may be capable of forming polymers containing siloxane linkages, Ge—O—Si linkages, and/or Ge—O—Ge linkages. In an exemplary embodiment, the silane group on the second silane may be represented by formula (VII):

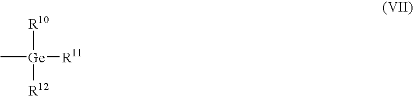

where R¹⁰, R¹¹, and R¹² may each be, independently, F, Cl, Br, I, H, OH, a methoxy group, an ethoxy group, an isopropoxy group, an alkoxy group, an acetoxy group, a methyl group, an alkyl group, a perfluoroalkyl group, a partially fluorinated alkyl group, a dimethylamino group, a dialkylamino group, an ethylamino group, a monoalkylamino group, an amino group, a phenyl group, or a methoxyethoxyethoxy group.

In at least one embodiment, the second silane may be represented by formula (VIII):

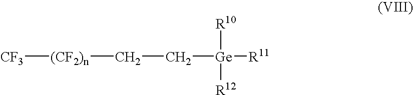

where n may be an integer from 0-32, and R¹⁰, R¹¹, and R¹² may be as defined above for formula (VII). In additional embodiments, n may be an integer from 1-16. In at least one embodiment, n may be an integer from 5-9.

FIGS. 2-9 show exemplary methods for forming a coating on a surface according various embodiments. Although reference is made in the figures and description to methods using silane compounds (e.g., the first silane and the second silane), germanium compounds analogous to the silane compounds may be utilized in conjunction with or in place of the silane compounds, without limitation. Additionally, combinations of silane compounds and geranium compounds may be used in the following methods, without limitation. In various embodiment, the methods illustrated in FIGS. 2-9 may be conducted at temperatures ranging from approximately 0° C. to approximately 350° C.

FIG. 2 is a flow diagram of an exemplary method 100 for forming coating 26 according to at least one embodiment. As illustrated in this figure, at 106 the first silane may be deposited onto surface 24. Adhesion promoting layer 28 may be formed from the deposition of first silane onto surface 24. At 114, the second silane may be deposited onto the first silane and/or adhesion promoting layer 28. Hydrophobic layer 30 may be formed from the deposition of the second silane onto the first silane and/or adhesion promoting layer 28. During 106, in which the first silane may be deposited onto surface 24, the first silane may be in a solid, liquid, or gaseous state. Deposition of the first silane onto surface 24 may be conducted using any suitable method, including for example, immersing surface 24 in a liquid comprising the first silane and/or exposing surface 24 to a vapor comprising the first silane and/or immersing surface 24 in a solution comprising the first silane. Some partial pressure of one or more inert gases may be present when the first silane is deposited on surface 24. In various embodiments, the first silane may be deposited under a pressure ranging from a few torr to above atmospheric pressure.

During or following 106, in which the first silane may be deposited onto surface 24, the first silane may become bonded to surface 24. In at least one embodiment, the first silane may become covalently bonded to surface 24 through, for example, a carbamate (i.e., urethane) linkage, an ester linkage, an ether linkage, an amide linkage, and/or a C—O—Si linkage. For example, a surface, such as a surface of a polymer substrate, may comprise a hydroxyl group.

In at least one example, a carbamate linkage may be formed between the first silane and surface 24 by a reaction between a hydroxyl group on surface 24 and an isocyanate group on the first silane. In an additional embodiment, an ester linkage may be formed between the first silane and surface 24 by a reaction between a hydroxyl group on surface 24 and an acyl chloride group on the first silane. In certain embodiments, an ether linkage may be formed between the first silane and surface 24 by a reaction between a hydroxyl group on surface 24 and an alkyl or benzyl chloride group on the first silane. In an additional embodiment, an ether linkage may be formed between the first silane and surface 24 by a reaction between a hydroxyl group on surface 24 and an epoxy or glycidyl group on the first silane. In an additional embodiment, an ester linkage may be formed between the first silane and surface 24 by a reaction between a hydroxyl group on surface 24 and a methyl ester group on the first silane. In an additional embodiment, a Si—O—C linkage may be formed between the first silane and surface 24 by a reaction between a hydroxyl group on surface 24 and a Si—Cl group, a Si—OCH₃ group, a Si—OCH₂CH₃ group, a Si—N(CH₃)₂ group, or a similar reactive group, on the first silane. In an additional embodiment, an amide linkage may be formed between the first silane and surface 24 by a reaction between a carboxyl group on surface 24 and an amine group on the first silane. In an additional embodiment, an ionic linkage may be formed between the first silane and surface 24 by a reaction between a carboxyl group on surface 24 and a primary amine group on the first silane to form an ion pair of the —COO⁻ and —NH₃⁺ groups. In an additional embodiment, an imine linkage may be formed between the first silane and surface 24 by a reaction between a carbonyl group on surface 24 and an amine group on the first silane.

Alternatively, a siloxane linkage and/or a Si—O—C linkage may be formed between the first silane and a surface of a silicon oxide based substrate by, for example, a reaction between a silane group on the first silane and a silanol (Si—OH) group on surface 24. An Al—O—Si linkage may also be formed between the first silane and a surface of an aluminum oxide based substrate by, for example, a reaction between a silane group on the first silane and an AlOH group on surface 24.

During 114, in which the second silane may be deposited onto the first silane, the second silane may be in a solid, liquid, or gaseous state. Deposition of the second silane onto surface 24 may be conducted using any suitable method, including for example, immersing surface 24 in a liquid comprising the second silane and/or exposing surface 24 to a vapor comprising the second silane. In certain embodiments, the second silane may be contained in a solution comprising a solvent. In various embodiments, the second silane film may be deposited under a pressure ranging from a few torr to above atmospheric pressure.

During or following 114, in which the second silane may be deposited onto the first silane, the second silane may become bonded to the first silane. In at least one embodiment, the second silane may become covalently bonded to the first silane through, for example, a siloxane (Si—O—Si) linkage. A siloxane linkage may be formed by a reaction between a silane group on the second silane and a silane group on the first silane. Prior to 114, a silane group on the first silane may be hydrolyzed to form a siloxyl (Si—OH) group. Subsequently, the siloxyl group on first silane may react with a silane group on the second silane to form a siloxane linkage.

In certain embodiments, prior to depositing the first silane onto surface 24, surface 24 may be oxidized. For example, as illustrated in FIG. 3, method 100 may further comprise 102 prior to 106. At 102, a portion of surface 24 may be oxidized. Surface 24 may be oxidized by, for example, exposing surface 24 to a plasma. In at least one embodiment, surface 24 may be oxidized by exposing surface 24 to an air plasma. Oxidation of surface 24 may introduce additional hydroxyl and/or siloxyl groups to surface 24. Exposing surface 24 to a plasma may also clean organic matter from surface 24.

In at least one embodiment, surface 24 may be oxidized by exposing surface 24 to an oxygen plasma. Surface 24 may also be oxidized by exposing surface 24 to a water plasma. In an additional embodiment, surface 24 may also be oxidized by exposing surface 24 to a plasma that contains oxygen and water. In an additional embodiment, surface 24 may be oxidized by exposing surface 24 to an argon plasma, and subsequently exposing the surface to air or an oxygen containing gaseous composition. In an additional embodiment, surface 24 may be oxidized by exposing surface 24 to a helium plasma, and subsequently exposing the surface to the air. In an additional embodiment, surface 24 may be oxidized by exposing surface 24 to an ultraviolet (UV) light. In an additional embodiment, surface 24 may be oxidized by exposing surface 24 to a solution containing an oxidizing agent.

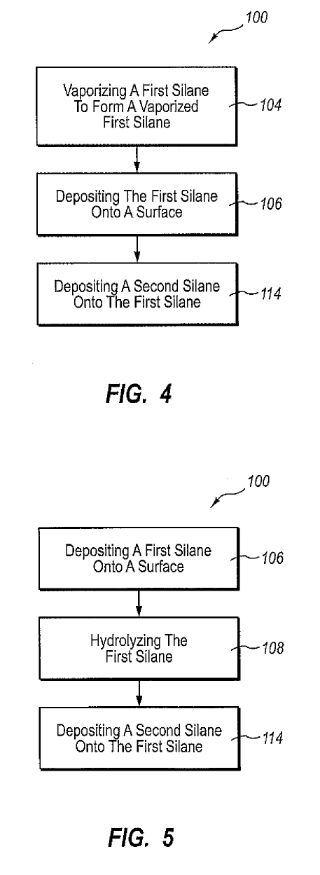

In various embodiments, the first silane may be vaporized prior to being deposited on surface 24. For example, as illustrated in FIG. 4, method 100 may further comprise 104 prior to 106. At 104, the first silane may by vaporized to form a vaporized first silane. At 106, the first silane may then be deposited through vapor deposition onto surface 24.

The first silane may be vaporized through any suitable method, including, for example, increasing the temperature and/or reducing the pressure of the first silane. In certain embodiments, a carrier solvent may be used to transport the first silane into a heated vacuum chamber, where the first silane may be vaporized. Substrate 22 may be present in a heated vacuum chamber in which the first silane may be vaporized.

Vapor deposition of the first silane may enable effective deposition and/or reaction of the first silane with surface 24, while reducing or eliminating the use of solvents to carry the first silane to desired portions of surface 24. Accordingly, vapor deposition of the first silane may effectively minimize solvent and/or other waste products in comparison with a solution based delivery system. Additionally, vapor deposition of the first silane may reduce or eliminate any need for cleaning surface 24 and the deposited first silane prior to 114, in which a second silane may deposited onto the first silane.

In at least one embodiment, the first silane may be hydrolyzed during or following deposition of the first silane onto surface 24. For example, as illustrated in FIG. 5, method 100 may further comprise 108 after 106 and prior to 114. At 108, the first silane may be hydrolyzed. Hydrolyzing the first silane may comprise, for example, exposing the first silane to liquid or vaporized water during or following deposition of the first silane onto surface 24. In certain embodiments, hydrolyzing the first silane may comprise vaporizing water by raising the water temperature and/or reducing the water pressure, and exposing the first silane deposited on surface 24 to the vaporized water. In various embodiments, hydrolysis may be conducted under a pressure ranging from a few torr to above atmospheric pressure.

Alternatively, hydrolysis may be promoted by water derived in-part or exclusively from the substrate material and/or reaction by-products. For example, in a case where surface 24 comprises a surface of a polymeric substrate, vaporized water may be produced from a decomposition or reaction of the polymeric substrate during method 100. Additionally, water may be present in the substrate itself, and may be released during method 100. The vaporized water may in turn hydrolyze the first silane.

During hydrolysis of the first silane, at least one silanol group (i.e., a Si—O—H group) may be formed on the first silane at the location of the silane group. The silanol group may act as an adhesion promoter for the second silane, providing a highly reactive site at which the second silane may bond to the first silane.

Hydrolysis of the first silane may lead to condensation between molecular components of the first silane, forming siloxane bonds between adjacent molecular components. The siloxane bonds between adjacent molecular components may result in cross-linking of the first silane deposited onto surface 24. Siloxane linkages between adjacent molecular components of the first silane may add structural robustness to the first silane deposited on surface, enabling formation of an ultra-thin adhesion promoting layer 28, which is relatively stable and abrasion resistant, on surface 24.

In various embodiments, exposing the first silane to the vaporized water may result in hydrolysis of at least one unreacted isocyanate group on the first silane, producing an amine group (i.e., —NH₂). An amine group on the first silane may act as a Brønsted-Lowry base, accepting protons and forming ionic bonds with carboxyl groups that may be present on surface 24. At elevated temperature, the amine group that has accepted a proton from a carboxyl group at the surface may form an amide linkage, with concomitant loss of water. The amine group may also form ionic bonds with silanol groups on the second silane deposited on the first silane. The amine group may also form ionic bonds with silanol groups in the adhesion promoting layer 28.

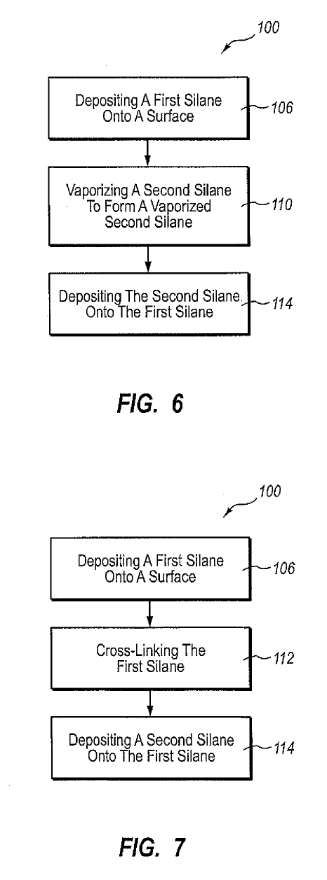

In additional embodiments, the second silane may be vaporized prior to being deposited on the first silane and/or adhesion promoting layer 28. For example, as illustrated in FIG. 6, method 100 may further comprise 110 following 106 and prior to 114. At 110, the second silane may by vaporized to form a vaporized second silane. At 114, the second silane may then be deposited through vapor deposition onto the first silane and/or adhesion promoting layer 28.

The second silane may be vaporized through any suitable method, including, for example, increasing the temperature and/or reducing the pressure of the second silane. In certain embodiments, a carrier solvent may be used to transport the second silane into a heated vacuum chamber, where the second silane may be vaporized. Substrate 22 may be present in a heated vacuum chamber in which the second silane may be vaporized.

Vapor deposition of the second silane may enable effective deposition and/or reaction of the second silane with the first silane while reducing or eliminating the use of solvents to carry the second silane to desired portions of the adhesion promoting layer 28. Accordingly, vapor deposition of the second silane may effectively minimize solvent and/or other waste products in comparison with a solution based delivery system. Additionally, vapor deposition of the second silane may reduce or eliminate any need for cleaning surface 24 and the deposited second silane following deposition of the second silane.

In various embodiments, after depositing the first silane onto surface 24, the first silane may be cross-linked. For example, as illustrated in FIG. 7, method 100 may further comprise 112 following 106. At 112, the first silane may be cross-linked.

Cross-linking of the first silane may be performed at any suitable time following deposition of the first silane on the substrate, including, for example, prior to or following deposition of the second silane on the first silane. Cross-linking of the first silane may be promoted through any suitable method, including, for example hydrolysis of the first silane. As described above, at 108, the first silane may be hydrolyzed. Hydrolysis of the first silane may lead to condensation between molecular components of the first silane, forming siloxane bonds between adjacent molecular components. The siloxane bonds between adjacent molecular components may result in cross-linking of the first silane deposited on surface 24. Siloxane linkages between adjacent molecular components of the first silane may add structural robustness to the first silane deposited on surface, enabling formation of an ultra-thin adhesion promoting layer 28, which is relatively stable and abrasion resistant, on surface 24.

In additional embodiments, a cross-linking compound may be used to promote and/or increase cross-linking between molecular components of the first silane. Examples of cross-linking compounds suitable for use in cross-linking the first silane include, without limitation, bis(trichlorosilyl)hexane and tetrakis(trichlorosilyethyl)-silane. The cross-linking compound may be bonded to molecular components of the first silane through any suitable means, including, for example, through hydrolysis. A cross-linking compound may promote increased branching between molecular components of the first silane, and may increase stability and abrasion resistance in adhesion promoting layer 28. In certain embodiments, polymerizable groups such as, for example, vinyl groups, may be introduced onto the first silane, and polymerization of the polymerizable groups may then be induced.

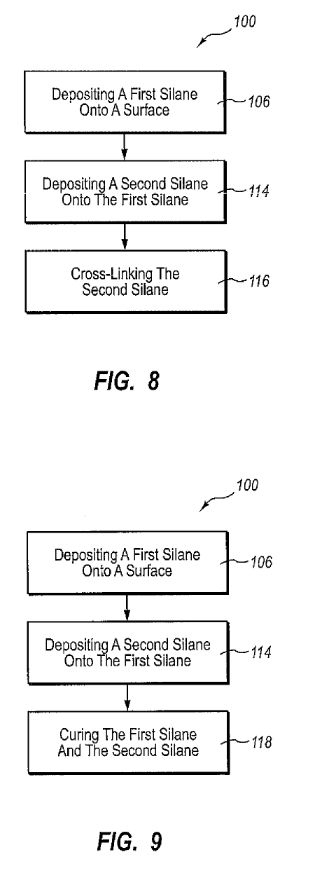

In various embodiments, after depositing the second silane onto surface 24, the second silane may be cross-linked. For example, as illustrated in FIG. 8, method 100 may further comprise 116 following 114. At 116, the second silane may be cross-linked.

Cross-linking of the second silane may be promoted through any suitable method, including, for example hydrolysis of the second silane. In certain embodiments, the second silane may be hydrolyzed by exposing the second silane to vaporized water during or following deposition of the second silane onto the first silane. Alternatively, hydrolysis may be promoted by water derived in-part or exclusively from the substrate material and/or reaction by-products. For example, in a case where surface 24 comprises a surface of a polymeric substrate, vaporized water may be produced from a decomposition or reaction of the polymeric substrate during method 100. Additionally, water may be present in the substrate itself, and may be released during method 100.

Hydrolysis of the second silane may lead to condensation between individual molecular components of the second silane, as well as between molecular components of the second silane and the first silane. The condensation may lead to the formation of siloxane bonds between adjacent molecular components. The siloxane bonds between adjacent molecular components may result in cross-linking of the second silane deposited onto surface 24. The siloxane bonds between adjacent molecular components may also result in cross-linking between the second silane and the first silane. Siloxane linkages between adjacent molecular components of the second silane and/or the first silane may add structural robustness to the coating composition, enabling an ultra-thin coating, which is relatively stable and abrasion resistant, to be deposited onto surface 24.

In additional embodiments, a cross-linking compound may be used to promote and/or increase cross-linking between molecular components of the second silane. Examples of cross-linking compounds suitable for use in cross-linking the second silane include, without limitation, bis(trichlorosilyl)hexane and tetrakis(trichlorosilyethyl)-silane. The cross-linking compound may be bonded to molecular components of the second silane through any suitable means, including, for example, through hydrolysis. A cross-linking compound may promote increased branching between molecular components of the second silane, and may increase stability and abrasion resistance in a coating of the second silane. In certain embodiments, polymerizable groups such as, for example, vinyl groups, may be introduced onto the second silane, and polymerization of the polymerizable groups may then be induced.

In certain embodiments, after depositing the first silane onto surface 24 and/or after depositing the second silane onto the first silane, the first silane and/or the second silane may be cured. For example, as illustrated in FIG. 9, method 100 may further comprise 118 following 114. 118 may comprise curing the second silane and/or the first silane to form a cured coating 26 on surface 24. The term “cure,” “cured,” or “curing” as used herein, refers to a change in state, condition, and/or structure of a material, and may include partial as well as complete curing.

Curing of the first silane and/or the second silane may be conducted using any suitable method, including, for example, exposing the first silane and/or the second silane to heat or radiation. In an exemplary embodiment, a coating comprising the first silane and the second silane may be cured by exposing the coating to an elevated temperature for a suitable period of time.

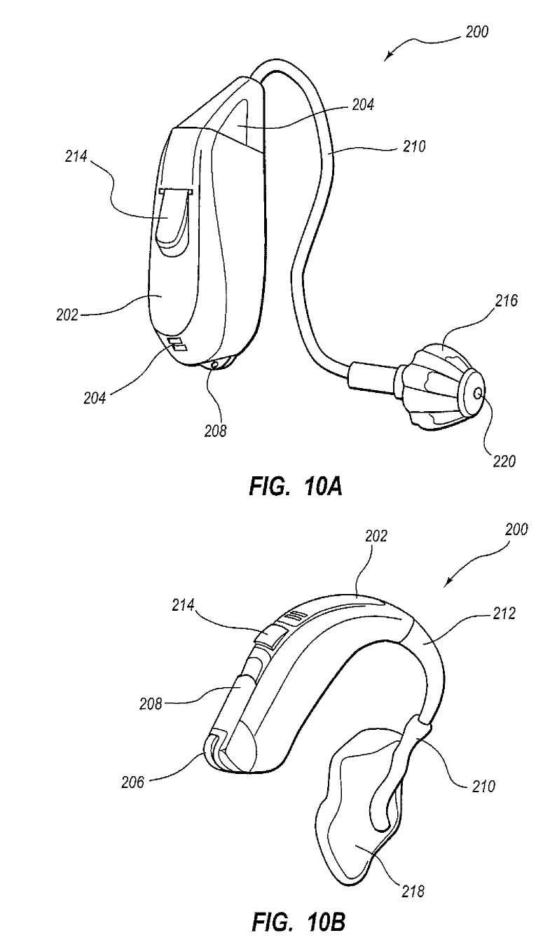

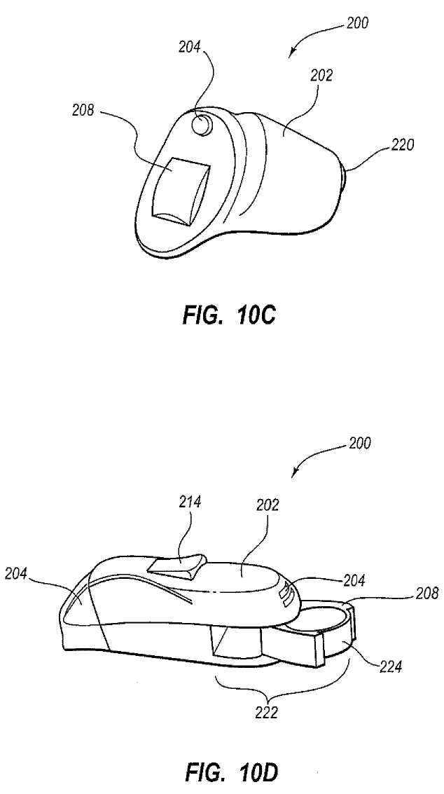

FIGS. 10A-10D show exemplary hearing aid devices according various embodiments. As illustrated in these figures, a hearing aid device 200 may comprise a device cover 202, a microphone cover 204, and a battery door 208. In at least one embodiment, as illustrated in FIG. 10A, hearing aid device 200 may be an open ear hearing aid. As shown in FIG. 10A, hearing aid device 200 may comprise a device cover 202, at least two microphone covers 204 (e.g., covering a front microphone and a rear microphone), a program button 214, tubing 210, an in-the-ear dome 216, and a sound port 220. Microphone covers 204 may comprise a mesh material. FIG. 10D shows an exemplary battery compartment 222 on a portion of hearing aid device 200, such as an open ear hearing aid. Battery compartment 222 may comprise a battery door 208, and a battery 224. The battery compartment 222 in FIG. 10D is shown in an open configuration.

In an additional embodiment, as illustrated in FIG. 10B, hearing aid device 200 may be a behind the ear (BTE) hearing aid. As shown in FIG. 10B, hearing aid device 200 may comprise a device cover 202, a battery door 208, a program button 214, a volume control 206, tubing 210, an ear hook 212, and an ear mold 218.

In an additional embodiment, as illustrated in FIG. 10C, hearing aid device 200 may be a custom hearing aid. As shown in FIG. 10B, hearing aid device 200 may comprise a device cover 202, a microphone cover 204, a battery door 208, and a sound port 220. Custom hearing aids may be designed to fit within a portion of the ear or canal. Examples of custom hearing aids include, without limitation, CIC (Completely in the Canal), MC (Mini Canal), ITC (In the Canal), ITE (In the Ear), and HS (Half Shell) hearing aids. Microphone cover 204 may comprise a mesh material.

Hearing aid device 200 may comprise coating 26 on, near, or adjacent to any suitable portion, including external and internal portions of hearing aid device 200. Additionally, any suitable component or portion thereof may comprise coating 26. Coating 26 may be formed on, near, or adjacent to any portion of hearing aid device 200 that may having an opening between an exterior portion and an interior portion of hearing aid device 200. Examples of portions of hearing aid device 200 that coating 26 may be formed on, near, or adjacent to include, without limitation, device cover 202, microphone cover 204, volume control 206, battery door 208, tubing 210, ear hook 212, program button 214, in-the-ear dome 216, ear mold 218, sound port 220, battery compartment 222, and/or battery 224.

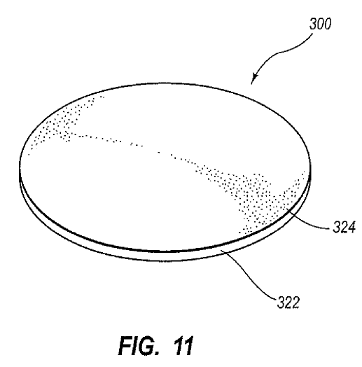

FIG. 11 is an exemplary silicon-based article, on a portion of which a coating is formed according to an additional embodiment. As illustrated in this figure, a silicon-based article 300 may include a substrate 322 and a substrate surface 324. Coating 26 may be formed on a surface portion of substrate 322, including, for example, substrate surface 324. Examples of silicon-based article 300 include, without limitation, silicon wafers, semiconductor devices, and integrated circuits. Silicon-based articles 300 may comprise any suitable material, including, for example, silicon and/or silicon oxide.

### EXAMPLES

The following examples are for illustrative purposes only and are not meant to be limiting on the scope of the appended claims.

### Reagents

Reagents used in the following examples include: (Tridecafluoro-1,1,2,2-tetrahydrooctyl)trichlorosilane (≧−97%, Aldrich), 3-isocyanatopropyltriethoxysilane (95%, Gelest, Morrisville, Pa.), triethoxy(1H,1H,2H,2H-perfluorooctyl)silane (98%, Aldrich), m-cresol (97%, Aldrich), and nylon 6/6 pellets (Aldrich, Cat. No. 181129). An “aqueous salt/acid” solution employed herein is a formulation for artificial sweat, which was 0.34 M NaCl, 0.08 M urea, 0.33 M NH₄Cl, 0.04 M CH₃COOH and 0.12 M lactic acid. The solution was adjusted to pH 4.7 with 2 M NaOH.

### Substrates

Substrates used in the following examples included silicon substrates, reinforced nylon substrates, and spin-coated nylon substrates. Silicon substrates used in the examples included silicon wafers (test grade, n-type, <1-0-0> orientation, 2-6 Ω-cm) from UniSil Corporation, California. The silicon wafers were cleaved into ca, 1.5×1.5 cm pieces. Prior to performing any surface chemistry on the silicon substrates, the silicon substrates were cleaned with an aqueous 2% sodium dodecyl sulfate (“SDS”) solution and water without sonication.

Reinforced nylon substrates used in the following examples included FDA grade reinforced nylon 6/6 surfaces containing 35% chopped glass fiber by weight (⅛- 3/16″ long). The FDA grade reinforced nylon surfaces contained FDA compliant additives (e.g., colorants) and no UV or high flow additives. Aldrich indicated the melting point of the nylon 6/6 they provided was 263° C., and its glass transition temperature was 45° C. Prior to performing any surface chemistry on the reinforced nylon substrates, the reinforced nylon substrates were sonicated in an SDS solution for 5 minutes. They were then sonicated in deionized water for 10 minutes. This water was changed three times during sonication.

Spin-coated nylon substrates used in the following examples included substrates prepared by spin-coating a solution of nylon 6/6 pellets in m-cresol onto surfaces of native oxide coated silicon wafers using the following program conditions (on an instrument from Laurell Technologies Corporation, model WS-400B-6NPP/LITE): 1000 rpm (10 seconds) followed by 5000 rpm (90 seconds). An initial concentration of the nylon 6/6 solution was <3% (w/w), but this nylon 6/6 solution was diluted in m-cresol until the spin-coating process obtained a film thickness of approximately 170 Å. The spin-coated nylon substrates were then baked in a vacuum oven at 100° C. for 2 hours at reduced pressure to drive off m-cresol.

### Surface Analytical Instrumentation

Time-of-flight secondary ion mass spectrometry (“TOF-SIMS”) was performed with an ION-TOF (TOF-SIMS IV) instrument with a two-lens, monoisotopic ⁶⁹Ga⁺ gun as a primary ion source. X-ray photoelectron spectroscopy (“XPS”) was performed with an SSX-100 instrument from Surface Sciences using an Al Kα source and a hemispherical analyzer. An electron flood gun was employed for charge compensation of the reinforced nylon samples, and this charge compensation was further enhanced by placing a fine Ni mesh ca. 0.5-1.0 mm above the surface of the glass reinforced polymer. No charge compensation was necessary for the silicon or spin-coated nylon on silicon samples. Water contact angles were measured with a Ramé-Hart (model 100-00) contact angle goniometer. Spectroscopic ellipsometry was performed with an M-2000 instrument from the J.A. Woollam Co., Inc. The wavelength range was 190.5-989.4 nm, and the angle of incidence was fixed at 75′. Silicon oxide, hydrocarbon, deposited silane films, and spin coated nylon were modeled using the same optical constants of silicon oxide that were found in the instrument software.

### Example 1

### Plasma Cleaning/Treatment of Silicon Substrate

Plasma cleaning/treatment of silicon substrates was performed by exposing the silicon substrates to an air plasma in a plasma cleaner (model PDC-32G from Harrick Plasma, Ithaca, N.Y.) at medium power (10.5 W applied to the RF coil) for 30 seconds. An advancing water contact angle (θₐ(H₂O)) for a silicon substrate surface was measured to be 40° prior to plasma cleaning/treatment. Following plasma cleaning/treatment, an average advancing water contact angle for a surface of silicon substrate prepared according to this example was measured to be <15°.

Advancing water contact angle may be used as a measure of surface hydrophobicity. A higher advancing water contact angle for a surface may indicate that the surface has a higher degree of hydrophobicity. A decrease in water contact angle for a surface following plasma cleaning/treatment may indicate an increase in oxygen content (e.g., —OH content) of the surface. A decrease in water contact angle for a surface following plasma cleaning/treatment may also indicate removal of hydrocarbon contamination from the surface as a result of the plasma cleaning/treatment.

### Example 2

### Plasma Cleaning/Treatment of Reinforced Nylon Substrate

Plasma cleaning/treatment of reinforced nylon substrates was performed by exposing the reinforced nylon substrates to an air plasma in a plasma cleaner (model PDC-32G from Harrick Plasma, Ithaca, N.Y.) at medium power (10.5 W applied to the RF coil) for 30 seconds.

An average advancing water contact angle for surfaces of three reinforced nylon substrates was measured to be 69° prior to plasma cleaning/treatment. Following plasma cleaning/treatment, an average advancing water contact angle for surfaces of five reinforced nylon substrates prepared according to this example was measured to be 32°.

Prior to plasma cleaning/treatment of a reinforced nylon substrate prepared according to this example, an X-ray photoelectron spectrum (“XP spectrum”) for the reinforced nylon substrate surface, obtained using XPS, was dominated by signals from oxygen (O1s), nitrogen (N1s), and carbon (C1s). Following plasma cleaning/treatment of the reinforced nylon substrate, O1s, N1s, and C1s signals still dominated the XP spectrum for the reinforced nylon substrate surface. However, a peak ratio of O1s to C1s for the reinforced nylon substrate surface increased significantly, from a ratio of 0.14 prior to plasma cleaning/treatment to a ratio of 0.28 following plasma cleaning/treatment, which indicates an increase in oxygen (e.g., —OH) content of the reinforced nylon substrate surface following plasma cleaning/treatment. Additionally, the C1s narrow scan of the XP spectrum for the reinforced nylon substrate surface showed a notable increase in a peak representing oxidized (i.e., chemically shifted) carbon, further indicating an increase in oxygen content of the reinforced nylon substrate following plasma cleaning/treatment.

The O⁻/C⁻ ratio in a negative ion TOF-SIMS spectrum of a reinforced nylon substrate surface prepared according to this example was 0.09 prior to plasma cleaning/treatment and was 0.21 following plasma cleaning/treatment, indicating an increase in oxygen content of the reinforced nylon substrate surface as a result of the plasma cleaning/treatment.

### Example 3

### Plasma Cleaning/Treatment of Spin Coated Nylon Substrate

Plasma cleaning/treatment of spin-coated nylon substrates was performed by exposing the spin-coated nylon substrates to an air plasma in a plasma cleaner (model PDC-32G from Harrick Plasma, Ithaca, N.Y.) at medium power (10.5 W applied to the RF coil) for 30 seconds.

An average advancing water contact angle for surfaces of five spin-coated nylon substrates was measured to be 60° prior to plasma cleaning/treatment. Following plasma cleaning/treatment, an average advancing water contact angle for surfaces of six spin-coated nylon substrates prepared according to this example was measured to be 34°.

### Example 4

### Preparation of NCO-Silane/Silicon Substrate

Following plasma cleaning/treatment according to Example 1, silicon substrates were dehydrated in a vacuum oven at 100° C. at reduced pressure. The vacuum for the vacuum oven was provided by a rotary vane pump. The vacuum oven contained a dry ice/acetone-cooled glass trap that prevented back-streaming of oil from the rotary vane pump and prevented both solvents and reagents from entering the rotary vane pump. After introducing the silicon substrates into the oven, the rotary vane pump was turned on for 3 minutes to attain a pressure of 15 Torr, and the valve to the rotary vane pump was then closed. The surfaces were allowed to dehydrate under these conditions for 30 minutes. The rotary vane pump was then turned on again for 3 minutes to pump off water vapors, after which the valve to the rotary vane pump was again closed.

An aliquot of 250 μL of 3-isocyanatopropyltriethoxysilane (“NCO-silane”) was then injected into the vacuum oven through a septum. The NCO-silane evaporated rapidly after being injected into the vacuum oven. The surfaces were allowed to react with the vapors of the NCO-silane under essentially static conditions for 30 minutes to form a silicon substrate having NCO-silane deposited on it (“NCO-silane/silicon substrate”). The valve to the rotary vane pump was then opened to pump off unreacted NCO-silane. Following plasma cleaning/treatment, an average advancing water contact angle for three NCO-silane/silicon substrates prepared according to this example was measured to be 82°.

Prior to deposition of NCO-silane on a silicon substrate, no N1s signal could be observed in an XP spectrum of the silicon substrate surface. Following deposition of NCO-silane on the silicon substrate to form an NCO-silane/silicon substrate surface according to this example, a small N1s signal was observable in an XP spectrum of the NCO-silane/silicon substrate surface. Spectroscopic ellipsometry of the NCO-silane/silicon substrate surface indicated that a layer having a thickness of 9.5 Å was present on the silicon substrate surface.

### Example 5

### Preparation of NCO-Silane/Reinforced Nylon Substrate

The procedure described for Example 4 was essentially followed with the exception that a reinforced nylon substrate prepared according to Example 2 was used instead of a silicon substrate to form a reinforced nylon substrate having NCO-silane deposited on it (“NCO-silane/reinforced nylon substrate”). Following deposition of NCO-silane, an average advancing water contact angle for five NCO-silane/reinforced nylon substrates prepared according to this example was measured to be 87°.

### Example 6

### Preparation of NCO-Silane/Spin-Coated Nylon Substrate

The procedure described for Example 4 was essentially followed with the exception that a spin-coated nylon substrate prepared according to Example 3 was used instead of a silicon substrate to form a spin-coated nylon substrate having NCO-silane deposited on it (“NCO-silane/spin-coated nylon substrate”). Following NCO silane deposition and plasma cleaning/treatment, the average advancing water contact angle for six NCO-silane/spin-coated nylon substrates prepared according to this example was measured to be 82°.

### Example 7

### Hydrolysis of NCO-silane/Silicon Substrate

NCO-silane/silicon substrates prepared according to Example 4 were left in a vacuum oven, and a Petri dish containing 5 ml of water was introduced into the vacuum oven. The door to the oven was closed and the NCO-silane/silicon substrates were allowed to hydrolyze at atmospheric pressure and 100° C. for 30 minutes to form NCO-silane/silicon substrates having hydrolyzed surfaces (“hydrolyzed NCO-silane/silicon substrates”).

### Example 8

### Hydrolysis of NCO-silane/Reinforced Nylon Substrate

NCO-silane/reinforced nylon substrates prepared according to Example 5 were left in a vacuum oven, and a Petri dish containing 5 ml of water was introduced into the vacuum oven. The door to the oven was closed and the NCO-silane/reinforced nylon substrates were allowed to hydrolyze at atmospheric pressure and 100° C. for 30 minutes to form NCO-silane/reinforced nylon substrates having hydrolyzed surfaces (“hydrolyzed NCO-silane/reinforced nylon substrates”).

### Example 9

### Hydrolysis of NCO-Silane/Spin-Coated Nylon Substrate

NCO-silane/spin-coated nylon substrates prepared according to Example 6 were left in a vacuum oven, and a Petri dish containing 5 ml of water was introduced into the vacuum oven. The door to the oven was closed and the NCO-silane/spin-coated nylon substrates were allowed to hydrolyze at atmospheric pressure and 100° C. for 30 minutes to form NCO-silane/spin-coated nylon substrates having hydrolyzed surfaces (“hydrolyzed NCO-silane/spin-coated nylon substrates”).

### Example 10

### Preparation of R_{f}-NCO-Silane/Silicon Substrate

Hydrolyzed NCO-silane/silicon substrates prepared according to Example 7 were placed in a desiccator along with an open vial of (tridecafluoro-1,1,2,2-tetrahydrooctyl)tri chlorosilane (“R_{f}-silane”) for 16 hours. The hydrolyzed NCO-silane/silicon substrates were then removed from the desiccator and cured in an oven at 80° C. for 1 hour to form NCO-silane/silicon substrates having R_{f}-silane deposited on their surfaces (“R_{f}-NCO-silane/silicon substrates”). Spectroscopic ellipsometry indicated that an average surface thickness of hydrolyzed NCO-silane/silicon substrates was 29.1 Å prior to exposure to R_{f}-silane and was 78.2 Å following exposure to R_{f}-silane to form R_{f}-NCO-silane/silicon substrates according to this example. The notable increase in thickness of the surfaces following exposure to R_{f}-silane may indicate cross-linking of R_{f}-silane molecules into a polymeric thin film on the substrate surfaces.

### Example 11

### Preparation of R_{f}-NCO-Silane/Reinforced Nylon Substrate

Hydrolyzed NCO-silane/reinforced nylon substrates prepared according to Example 8 were placed in a desiccator along with an open vial of R_{f}-silane for 16 hours. The hydrolyzed NCO-silane/reinforced nylon substrates were then removed from the desiccator and cured in an oven at 80° C. for 1 hour to form NCO-silane/reinforced nylon substrates having R_{f}-silane deposited on their surfaces (“R_{f}-NCO-silane/reinforced nylon substrates”).

An XPS analysis of an R_{f}-NCO-silane/reinforced nylon substrate prepared according to this example showed that an F1s signal, with its accompanying F Auger peaks, was the dominant signal in the XP spectrum. A split carbon signal was observed and indicated the presence of i) carbon bonded to carbon and/or hydrogen and/or mildly oxidized carbon at lower binding energy, and ii) carbon in CF₂ groups at higher binding energy, where each F atom bonded to a C atom is known to shift the C1s signal by ca. 2.9 eV, and secondarily shift carbon atoms by ca. 0.7 eV. No N 1s signal was observable in the XP spectrum, indicating that the R_{f}-silane may have formed a film that was free from pinhole defects and/or that was relatively thick in all places. A small oxygen signal was also present in the XP spectrum, which would be expected from Si—O linkages.

### Example 12

### Preparation of R_{f}-NCO-Silane/Spin-Coated Nylon Substrate

Hydrolyzed NCO-silane/spin-coated nylon substrates prepared according to Example 9 were placed in a desiccator along with an open vial of R_{f}-silane for 16 hours. The hydrolyzed NCO-silane/spin-coated nylon substrates were then removed from the desiccator and cured in an oven at 80° C. for 1 hour to form NCO-silane/spin-coated nylon substrates having R_{f}-silane deposited on their surfaces (“R_{f}-NCO-silane/spin-coated nylon substrates”). Spectroscopic ellipsometry indicated that a surface thickness of a hydrolyzed NCO-silane/spin-coated nylon substrate was 125.9 Å prior to exposure to R_{f}-silane and was 272.3 Å following exposure to R_{f}-silane to form a R_{f}-NCO-silane/spin-coated nylon substrate according to this example. The notable increase in thickness of the surfaces following exposure to R_{f}-silane may indicate crosslinking of R_{f}-silane molecules into a polymeric thin film on the substrate surfaces.

### Example 13

### Abrasion Testing of R_{f}-NCO-silane/Reinforced Nylon Substrate

An abrasion apparatus for testing abrasion resistance consisted of an electrical drill (Craftsman, Model No. 315.101160) that was clamped vertically relative to a bench top. A commercially available polishing disk (Craftsman), which is designed to be used with an electric drill, was attached to the chuck of the drill, and a piece of abrasive felt (15 cm×14.7 cm) was pasted onto the polishing disk. When the drill was turned on, it caused the felt disk to rotate parallel to the bench top. A sample holder was made from two rectangular strips of plywood joined end-to-end with a steel hinge. The end of one of the rectangular strips was clamped to a stand, and a sample was attached to the end of the other rectangular strip with double-sided tape. The sample was then placed on the felt wheel 4.5 cm from its center, and remained in contact with the felt wheel as the felt wheel rotated. A brass cylinder weighing 164 g was placed directly above the sample on the wood strip. The rotational speed of the drill was controlled with a powerstat and the felt was also marked on its edge so as to count the number of cycles during the abrasion tests.

Additionally, a reinforced nylon substrate was plasma cleaned/treated according to Example 2. Following plasma cleaning/treatment, the reinforced nylon substrate was hydrolyzed with a similar surface that had been treated with the NCO silane, and then placed in a desiccator along with an open vial of (tridecafluoro-1,1,2,2-tetrahydrooctyl)trichlorosilane for 16 hours. The reinforced nylon substrate was then removed from the desiccator and cured in an oven at 80° C. for 1 hour to form reinforced nylon substrates having R_{f}-silane deposited on its surface, with no NCO-silane between the R_{f}-silane and the surface of the reinforced nylon substrate.

An R_{f}-NCO-silane/reinforced nylon substrate prepared according to Example 11 and the reinforced nylon substrate containing R_{f}-Silane and no NCO-silane were each tested using the abrasion apparatus. After more than 430 cycles in the abrasion testing apparatus, the advancing water contact angle of the surface of the R_{f}-NCO-silane/reinforced nylon substrate prepared according to Example 11 was 10° higher than the advancing water contact angle of the surface of the reinforced nylon substrate containing R_{f}-Silane and no NCO-silane.

An XP spectrum of the substrate surfaces following abrasion testing indicated that the ratio of C:F for the R_{f}-NCO-silane/reinforced nylon substrate prepared according to Example 11 was 43:57, while the C:F ratio for the reinforced nylon substrate containing R_{f}-Silane and no NCO-silane was 49:51, indicating a higher concentration of R_{f}-silane on the surface of the R_{f}-NCO-silane/reinforced nylon substrate prepared according to Example 11. The narrow scan of the XP spectra shows a peak for C attached to F atoms is comparatively larger in intensity for the surface of R_{f}-NCO-silane/reinforced nylon substrate prepared according to Example 11, further indicating a higher concentration of R_{f}-silane on the surface.

### Example 14

### TOF-SIMS Analysis of Substrate Surfaces

TOF-SIMS analysis in both the negative and positive ion modes was performed on silicon oxide, reinforced nylon, and spin-coated nylon substrates after treatment with the NCO-silane, and again after treatment with the R_{f}-silane TOF-SIMS analysis, which has an information depth of only about 2 nm, is typically more surface sensitive than XPS analysis, which probes at least 10 nm into a material. Positive ion TOF-SIMS spectra of a R_{f}-NCO-silane/silicon substrate prepared according to Example 10, a R_{f}-NCO-silane/reinforced nylon substrate prepared according to Example 11, and a R_{f}-NCO-silane/spin-coated nylon substrate prepared according to Example 10 each showed a series of peaks that are characteristic of a perfluorinated hydrocarbon. The two largest peaks in the TOF-SIMS spectra were identified as the CF⁺ and CF₃⁺ peaks. The negative ion spectra from the R_{f}-NCO-silane/silicon substrate, the R_{f}-NCO-silane/reinforced nylon substrate, and the R_{f}-NCO-silane/spin-coated nylon substrate were dominated by a single F⁻ peak, and also showed an F₂⁻ peak, which is typically less than 5% intense as the F⁻ signal.

### Example 15

### Analysis of Surface Layer Thickness

Plasma treated silicon substrates and spin-coated nylon substrates, each having no NCO-silane deposited on the surfaces, were hydrolyzed. Silicon substrates and spin-coated nylon substrates with NCO-silane deposited on their surfaces were also hydrolyzed. Each of the substrates in this example were then placed in a desiccator along with an open vial of R_{f}-silane for 16 hours, after which they were cured in an oven at 80° C. for 1 hour.

Spectroscopic ellipsometry indicated that surfaces of the silicon substrates having no NCO-silane deposited on them had an average coating thickness of 116.7 Å, and surfaces of the spin-coated substrates having no NCO-silane deposited on them had an average coating thickness of 232.7 Å. Spectroscopic ellipsometry indicated that surfaces of the silicon substrates with NCO-silane deposited on them had an average coating thickness of 48.0 Å, and surfaces of the spin-coated substrates having NCO-silane deposited on them had an average coating thickness of 67.0 Å. Accordingly, the spectroscopic ellipsometry analysis indicates that the surfaces coated with the NCO-silane were considerably thinner than the surfaces that were not treated with the NCO.

### Example 16

### Plasma Cleaning/Treatment of Reinforced Nylon Substrate Using YES System

Reinforced nylon substrates were cleaned/treated in O₂ plasma using a YES 1224 P Chemical Vapor Deposition System manufactured by Yield Engineering Systems, Inc., California (“YES System”). Various time periods were used. Table 1 shows advancing water contact angles for reinforced nylon substrates exposed to O₂ plasma for various time periods according to this example.

TABLE 1

| Plasma | Advancing |
|---|---|
| treatment time | water contact |
| (minutes) | angle (θₐ(H₂O)) |
| 1 | 47° |
| 2.5 | 45° |
| 5 | 37° |
| 7.5 | 34° |

### Example 17

### Preparation of NCO-Silane/Silicon Substrate Using Yes System

Silicon substrates were cleaned/treated in O₂ plasma for 6 minutes using the YES System. The silicon substrates were then exposed to NCO-silane vapor for 10 minutes at a temperature of 100° C. to form an NCO-silane/silicon substrate. An advancing water contact angle for an NCO-silane/silicon substrate prepared according to this example was measured to be 55°. Spectroscopic ellipsometry of a silicon substrate surface and an NCO-silane/silicon substrate surface prepared according to this example indicated an increase in the thickness of the silicon substrate surface of 11.8 Å as a result of the NCO-silane deposition.

### Example 18

### Preparation of NCO-Silane/Reinforced Nylon Substrate Using Yes System

Reinforced nylon substrates were cleaned/treated in O₂ plasma for 6 minutes using the YES System. The reinforced nylon substrates were then exposed to NCO-silane vapor for 10 minutes at a temperature of 100° C. to form an NCO-silane/reinforced nylon substrate. An advancing water contact angle for an NCO-silane/reinforced nylon substrate prepared according to this example was measured to be 76°.

### Example 19

### Preparation of R_{f}-NCO-Silane/Silicon Substrate Using YES System

Following preparation of NCO-silane/silicon substrates according to Example 17, 3 mL of water was introduced into a chamber in the YES system to produce water vapor in the chamber. The NCO-silane/silicon substrates were hydrolyzed by exposing them to the water vapor in the chamber for 30 minutes at a temperature of 100° C. The NCO-silane/silicon substrates were then exposed to R_{f}-NCO-silane vapor for 15 minutes at a temperature of 100° C. to form R_{f}-NCO-silane/silicon substrates. An advancing water contact angle for an R_{f}-NCO-silane/silicon substrate prepared according to this example was measured to be 125°.

### Example 20

### Preparation of R_{f}-NCO-Silane/Reinforced Nylon Substrate Using Yes System

Following preparation of NCO-silane/reinforced nylon substrates according to Example 18, 3 mL of water was introduced into a chamber containing the NCO-silane/reinforced nylon substrates in the YES system to produce water vapor in the chamber. The NCO-silane/reinforced nylon substrates were hydrolyzed by exposing them to the water vapor in the chamber for 30 minutes at a temperature of 100° C. The NCO-silane/reinforced nylon substrates were then exposed to R_{f}-silane vapor for 15 minutes at a temperature of 100° C. to form R_{f}-NCO-silane/reinforced nylon substrates. An average advancing water contact angle for R_{f}-NCO-silane/reinforced nylon substrates prepared according to this example was measured to be 155°.

The preceding description has been provided to enable others skilled in the art to best utilize various aspects of the exemplary embodiments described herein. This exemplary description is not intended to be exhaustive or to be limited to any precise form disclosed. Many modifications and variations are possible without departing from the spirit and scope of the instant disclosure. The embodiments described herein are in all respects illustrative and not restrictive.

Unless otherwise noted, the terms “a” or “an,” as used in the specification and claims, are to be construed as meaning “at least one of.” In addition, for ease of use, the words “including” and “having,” as used in the specification and claims, are interchangeable with and have the same meaning as the word “comprising.”

What is claimed is:

1. A method, comprising:
(a) depositing a first silane onto a surface, the first silane comprising a functional linking group and a silane group;
(b) depositing a second silane onto the first silane, the second silane comprising a hydrophobic aliphatic group and a silane group.

2. The method of claim 1, wherein the functional linking group of the first silane comprises at least one of:
an isocyanate group;
an acyl halide group;
an epoxide group;
a glycidyl group;
an amino group;
a methyl ester group;
an isothiocyanato group;
a carboxyl group;
an activated carboxyl group;
an alkyl halide group;
a benzyl halide group;
a chlorosilane group;
a methoxysilane group;
an ethoxysilane group.

3. The method of claim 1, wherein the silane group of the first silane comprises a group represented by: 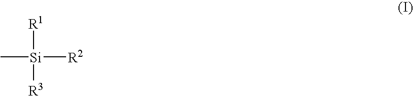
wherein R¹, R², and R³ are each, independently, F, Cl, Br, I, H, OH, a methoxy group, an ethoxy group, an isopropoxy group, an alkoxy group, an acetoxy group, a methyl group, an alkyl group, a perfluoroalkyl group, a partially fluorinated alkyl group, a dimethylamino group, a dialkylamino group, an ethylamino group, a monoalkylamino group, an amino group, a phenyl group, or a methoxyethoxyethoxy group.

4. The method of claim 1, wherein the first silane comprises a structure represented by: 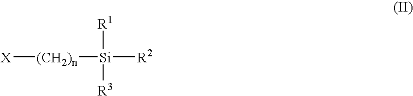
wherein:
n=0 to 32;
X is an isocyanate group, an acyl chloride group, an epoxide group, a glycidyl group, an amino group, a methyl ester group, an isothiocyanato group, a carboxyl group, an activated carboxyl group, an alkyl chloride group, an alkyl bromide group, an alkyl iodide group, a benzyl chloride group, a benzyl bromide group, a chlorosilane group, a methoxysilane group, an ethoxysilane group;
R¹, R², and R³ are each, independently, F, Cl, Br, I, H, OH, a methoxy group, an ethoxy group, an isopropoxy group, an alkoxy group, an acetoxy group, a methyl group, an alkyl group, a perfluoroalkyl group, a partially fluorinated alkyl group, a dimethylamino group, a dialkylamino group, an ethylamino group, a monoalkylamino group, an amino group, a phenyl group, or a methoxyethoxyethoxy group.

5. The method of claim 1, wherein the hydrophobic aliphatic group of the second silane comprises at least one of:
an alkyl chain;
a partially fluorinated alkyl chain;
a perfluorinated alkyl chain.

6. The method of claim 1, wherein the silane group of the second silane comprises a group represented by: 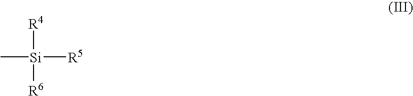
wherein R⁴, R⁵, and R⁶ are each, independently, F, Cl, Br, I, H, OH, a methoxy group, an ethoxy group, an isopropoxy group, an alkoxy group, an acetoxy group, a methyl group, an alkyl group, a perfluoroalkyl group, a partially fluorinated alkyl group, a dimethylamino group, a dialkylamino group, an ethylamino group, a monoalkylamino group, an amino group, a phenyl group, or a methoxyethoxyethoxy group.

7. The method of claim 1, wherein the second silane comprises a structure represented by: 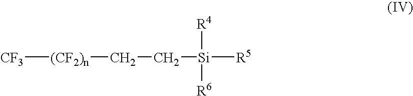
wherein:
n=0 to 32;
R⁴, R⁵, and R⁶ are each, independently, F, Cl, Br, I, H, OH, a methoxy group, an ethoxy group, an isopropoxy group, an alkoxy group, an acetoxy group, a methyl group, an alkyl group, a perfluoroalkyl group, a partially fluorinated alkyl group, a dimethylamino group, a dialkylamino group, an ethylamino group, a mono alkylamino group, an amino group, a phenyl group, or a methoxyethoxyethoxy group.

8. The method of claim 1, wherein the surface comprises a surface of a polymeric substrate.

9. The method of claim 1, wherein the surface comprises a surface of a silicon based substrate.

10. The method of claim 1, wherein the surface comprises a hydroxyl group.

11. The method of claim 10, wherein (a) comprises bonding the first silane to the surface by reacting the first silane with the hydroxyl group of the surface.

12. The method of claim 1, wherein the surface comprises a surface of a silicon based substrate comprising a silanol group.

13. The method of claim 12, wherein (a) comprises bonding the first silane to the surface by reacting a silane group of the first silane with the silanol group of the silicon based substrate to form a siloxane linkage.

14. The method of claim 1, further comprising, prior to (a):
(c) oxidizing a portion of the surface.

15. The method of claim 14, wherein (c) comprises exposing the surface to at least one of:
a plasma;
an oxidizing agent;
ultraviolet light.

16. The method of claim 1, further comprising, prior to (b):
(d) hydrolyzing the first silane.

17. The method of claim 16, wherein (d) comprises hydrolyzing the silane group on the first silane to form a silanol group.

18. The method of claim 17, wherein (b) comprises bonding the second silane to the first silane by reacting the silane group of the second silane with the silanol group of the first silane to form a siloxane linkage.

19. The method of claim 16, wherein (d) comprises exposing the first silane to moisture.

20. The method of claim 1, further comprising, prior to (a):
(e) vaporizing the first silane to form a vaporized first silane.

21. The method of claim 20, wherein (a) comprises exposing the substrate to the vaporized first silane.

22. The method of claim 1, further comprising, prior to (b):
(f) vaporizing the second silane to form a vaporized second silane.

23. The method of claim 22, wherein (b) comprises exposing the first silane to the vaporized second silane.

24. The method of claim 1, further comprising:
(g) cross-linking at least one of:
the first silane;
the second silane.

25. The method of claim 1, further comprising:
(h) curing at least one of:
the first silane;
the second silane.

26. A composition of matter, comprising the reaction product of:
a substrate comprising a hydroxyl group;
a first silane comprising a functional linking group and a silane group;
a second silane comprising a hydrophobic aliphatic group and a silane group.

27. The composition of matter of claim 26, wherein the functional linking group comprises at least one of:
an isocyanate group;
an acyl halide group;
an epoxide group;
a glycidyl group;
an amino group;
a methyl ester group;
an isothiocyanato group;
a carboxyl group;
an activated carboxyl group;
an alkyl halide group;
a benzyl halide group;
a chlorosilane group;
a methoxysilane group;
an ethoxysilane group.

28. The composition of matter of claim 26, wherein the first silane is bonded to the substrate by at least one of:
a carbamate linkage;
an ester linkage;
an ether linkage;
a Si—O—C linkage;
an amide linkage;
an imine linkage;
an ionic linkage;
a siloxane linkage.

29. The composition of matter of claim 26, wherein the silane group of the first silane comprises a group represented by: 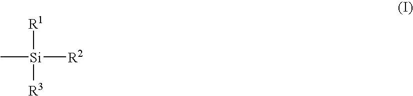
wherein R¹, R², and R³ are each, independently, F, Cl, Br, I, X, OH, a methoxy group, an ethoxy group, an isopropoxy group, an alkoxy group, an acetoxy group, a methyl group, an alkyl group, a perfluoroalkyl group, a partially fluorinated alkyl group, a dimethylamino group, a dialkylamino group, an ethylamino group, a monoalkylamino group, an amino group, a phenyl group, or a methoxyethoxyethoxy group.

30. The composition of matter of claim 26, wherein the first silane comprises a structure represented by: 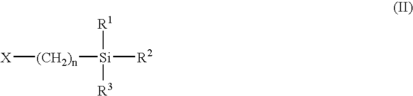
wherein:
n=0 to 32;
X is an isocyanate group, an acyl chloride group, an epoxide group, a glycidyl group, an amino group, a methyl ester group, an isothiocyanato group, a carboxyl group, an activated carboxyl group, an alkyl chloride group, an alkyl bromide group, an alkyl iodide group, a benzyl chloride group, a benzyl bromide group, a chlorosilane group, a methoxysilane group, an ethoxysilane group;
R¹, R², and R³ are each, independently, F, Cl, Br, I, H, OH, a methoxy group, an ethoxy group, an isopropoxy group, an alkoxy group, an acetoxy group, a methyl group, an alkyl group, a perfluoroalkyl group, a partially fluorinated alkyl group, a dimethylamino group, a dialkylamino group, an ethylamino group, a monoalkylamino group, an amino group, a phenyl group, or a methoxyethoxyethoxy group.

31. The composition of matter of claim 26, wherein the hydrophobic aliphatic group of the second silane comprises at least one of:
an alkyl chain;
a partially fluorinated alkyl chain;
a perfluorinated alkyl chain

32. The composition of matter of claim 26, wherein the silane group of the second silane comprises a group represented by: 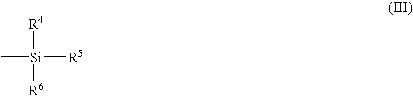
wherein R⁴, R⁵, and R⁶ are each, independently, F, Cl, Br, I, H, OH, a methoxy group, an ethoxy group, an isopropoxy group, an alkoxy group, an acetoxy group, a methyl group, an alkyl group, a perfluoroalkyl group, a partially fluorinated alkyl group, a dimethylamino group, a dialkylamino group, an ethylamino group, a monoalkylamino group, an amino group, a phenyl group, or a methoxyethoxyethoxy group.

33. The composition of matter of claim 26, wherein the second silane comprises a structure represented by: 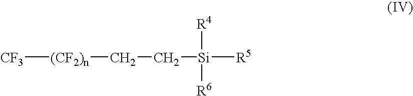
wherein:
n=0 to 32;
R⁴, R⁵, and R⁶ are each, independently, F, Cl, Br, I, H, OH, a methoxy group, an ethoxy group, an isopropoxy group, an alkoxy group, an acetoxy group, a methyl group, an alkyl group, a perfluoroalkyl group, a partially fluorinated alkyl group, a dimethylamino group, a dialkylamino group, an ethylamino group, a monoalkylamino group, an amino group, a phenyl group, or a methoxyethoxyethoxy group.

34. The composition of matter of claim 26, wherein the substrate comprises a polymeric substrate.

35. The composition of matter of claim 26, wherein the substrate comprises a silicon based substrate.

36. The composition of matter of claim 26, wherein the first silane comprises cross-linked portions comprising siloxane linkages.

37. The composition of matter of claim 26, wherein the second silane comprises cross-linked portions comprising siloxane linkages.

38. An article, comprising:
a first portion having a surface;
a coating composition bonded to the surface of the first portion, the coating composition comprising:
a first silane bonded to the surface of the first portion, the first silane comprising a silane group;
a second silane bonded to the first silane by a siloxane linkage, the second silane comprising a hydrophobic aliphatic group.

39. The article of 38, wherein the first silane is bonded to the surface of the first portion by at least one of:
a carbamate linkage;
an ester linkage;
an ether linkage;
a Si—O—C linkage;
an amide linkage;
an imine linkage;
an ionic linkage;
a siloxane linkage.

40. The article of claim 38, wherein the first silane comprises a silane group represented by: 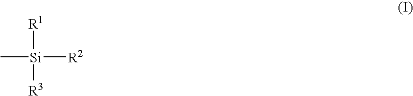
wherein R¹, R², and R³ are each, independently, F, Cl, Br, I, H, OH, a methoxy group, an ethoxy group, an isopropoxy group, an alkoxy group, an acetoxy group, a methyl group, an alkyl group, a perfluoroalkyl group, a partially fluorinated alkyl group, a dimethylamino group, a dialkylamino group, an ethylamino group, a monoalkylamino group, an amino group, a phenyl group, a methoxyethoxyethoxy group, or a siloxane linkage.

41. The article of claim 38, wherein the first silane comprises a structure represented by: 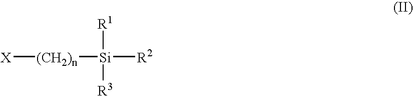
wherein:
n=0 to 32;
X is an isocyanate group, an acyl chloride group, an epoxide group, a glycidyl group, an amino group, a methyl ester group, an isothiocyanato group, a carboxyl group, an activated carboxyl group, an alkyl chloride group, an alkyl bromide group, an alkyl iodide group, a benzyl chloride group, a benzyl bromide group, a chlorosilane group, a methoxysilane group, an ethoxysilane group, a carbamate linkage, an ester linkage, an ether linkage, a Si—O—C linkage, an amide linkage, an imine linkage, an ionic linkage, or a siloxane linkage;
R¹, R², and R³ are each, independently, F, Cl, Br, I, H, OH, a methoxy group, an ethoxy group, an isopropoxy group, an alkoxy group, an acetoxy group, a methyl group, an alkyl group, a perfluoroalkyl group, a partially fluorinated alkyl group, a dimethylamino group, a dialkylamino group, an ethylamino group, a monoalkylamino group, an amino group, a phenyl group, a methoxyethoxyethoxy group, or a siloxane linkage.

42. The article of claim 38, wherein the hydrophobic aliphatic group of the second silane comprises at least one of:
an alkyl chain;
a partially fluorinated alkyl chain;
a perfluorinated alkyl chain.

43. The article of claim 38, wherein the second silane comprises a silane group represented by: 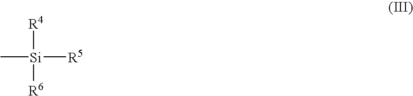
wherein R⁴, R⁵, and R⁶ are each, independently, F, Cl, Br, I, H, OH, a methoxy group, an ethoxy group, an isopropoxy group, an alkoxy group, an acetoxy group, a methyl group, an alkyl group, a perfluoroalkyl group, a partially fluorinated alkyl group, a dimethylamino group, a dialkylamino group, an ethylamino group, a monoalkylamino group, an amino group, a phenyl group, a methoxyethoxyethoxy group, or a siloxane linkage.

44. The article of claim 38, wherein the second silane comprises a structure represented by: 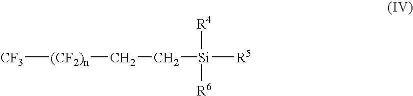
wherein:
n=0 to 32;
R⁴, R⁵, and R⁶ are each, independently, F, Cl, Br, I, H, OH, a methoxy group, an ethoxy group, an isopropoxy group, an alkoxy group, an acetoxy group, a methyl group, an alkyl group, a perfluoroalkyl group, a partially fluorinated alkyl group, a dimethylamino group, a dialkylamino group, an ethylamino group, a monoalkylamino group, an amino group, a phenyl group, a methoxyethoxyethoxy group, or a siloxane linkage.

45. The article of claim 38, further comprising an opening defined in the surface of the first portion.

46. The article of claim 45, wherein the coating composition is bonded to the surface of the first portion at a region adjacent to the opening defined in the surface of the first portion.

47. The article of claim 45, wherein the opening has an opening surface defining a portion of the opening extending through a portion of the article, and wherein the coating composition is bonded to the opening surface.

48. The article of claim 45, wherein the coating composition is capable of preventing a liquid from passing through the opening.

49. The article of claim 38, wherein the surface of the first portion comprises a mesh surface, the mesh surface comprising openings defined in the mesh surface.

50. The article of claim 38, further comprising a second portion having a surface, wherein an opening is defined between the surface of the first portion and the surface of the second portion.

51. An apparatus, comprising:
a hearing aid device, the hearing aid device comprising:
a first component, the first component having a surface portion;
a coating composition bonded to the surface portion of the first component, the coating composition comprising:
an adhesion layer bonded to the surface portion of the first component;
a hydrophobic layer bonded to the adhesion layer.

52. The apparatus of claim 51, wherein the hydrophobic layer comprises a hydrophobic aliphatic group comprising at least one of:
an alkyl chain;
a partially fluorinated alkyl chain;
a perfluorinated alkyl chain.

53. The apparatus of claim 51, wherein the adhesion layer is bonded to the surface portion of the first component by at least one of:
a carbamate linkage;
an ester linkage;
an ether linkage;
a Si—O—C linkage;
an amide linkage;
an imine linkage;
an ionic linkage;
a siloxane linkage.

54. The apparatus of claim 51, wherein the hydrophobic layer is bonded to the adhesion layer by at least one of:
a siloxane linkage;
a Si—O—Ge linkage;
a Ge—O—Ge linkage.

55. The apparatus of claim 51, wherein portions of the coating composition are cross-linked.

56. The apparatus of claim 51, wherein the first component comprises an opening defined in the surface portion of the first component.

57. The apparatus of claim 56, wherein the coating composition is bonded to the surface portion of the first component at a region adjacent to the opening defined in the surface portion of the first component.

58. The article of claim 56, wherein the opening has an opening surface defining a portion of the opening extending through a portion of the first component, and wherein the coating composition is bonded to the opening surface.

59. The apparatus of claim 51, further comprising a second component having a surface portion.

60. The apparatus of claim 59, further comprising a coating composition bonded to the surface portion of the second component, the coating composition comprising:
an adhesion layer bonded to the surface portion of the second component;
a hydrophobic layer bonded to the adhesion layer.

61. The apparatus of claim 59, wherein the surface portion of the first component is positioned adjacent to the surface portion of the second component; and
wherein an opening is defined between the surface portion of the first component and the surface portion of the second component.

62. The apparatus of claim 61, wherein the coating composition is bonded to the surface of the first portion in a quantity sufficient to prevent a liquid from passing through the opening.

63. The apparatus of claim 62, wherein the coating composition is bonded to the surface of the first portion in a quantity sufficient to permit a gas to pass through the opening.

64. The apparatus of claim 51, wherein the hearing aid device comprises at least one of:
a shell component;
a volume controller;
a battery door;
a microphone cover.

65. The apparatus of claim 51, wherein the hearing aid device comprises a hearing aid accessory, the hearing aid accessory comprising at least one of:
a battery;
a battery contact.

66. A method, comprising:
(a) depositing a first silane onto a surface portion of a hearing aid device, the first silane comprising a functional linking group and a silane group;
(b) depositing a second silane onto the first silane, the second silane comprising a hydrophobic aliphatic group and a silane group.

67. The method of claim 66, wherein the functional linking group of the first silane comprises at least one of:
an isocyanate group;
an acyl halide group;
an epoxide group;
a glycidyl group;
an amino group;
a methyl ester group;
an isothiocyanato group;
a carboxyl group;
an activated carboxyl group;
an alkyl halide group;
a benzyl halide group;
a chlorosilane group;
a methoxysilane group;
an ethoxysilane group.

68. The method of claim 66, wherein the silane group of the first silane comprises a group represented by: 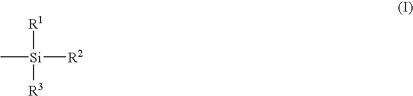
wherein R¹, R², and R³ are each, independently, F, Cl, Br, I, H, OH, a methoxy group, an ethoxy group, an isopropoxy group, an alkoxy group, an acetoxy group, a methyl group, an alkyl group, a perfluoroalkyl group, a partially fluorinated alkyl group, a dimethylamino group, a dialkylamino group, an ethylamino group, a monoalkylamino group, an amino group, a phenyl group, or a methoxyethoxyethoxy group.

69. The method of claim 66, wherein the first silane comprises a structure represented by: 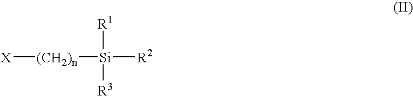
wherein:
n=0 to 32;
X is an isocyanate group, an acyl chloride group, an epoxide group, a glycidyl group, an amino group, a methyl ester group, an isothiocyanato group, a carboxyl group, an activated carboxyl group, an alkyl chloride group, an alkyl bromide group, an alkyl iodide group, a benzyl chloride group, a benzyl bromide group, a chlorosilane group, a methoxysilane group, an ethoxysilane group;
R¹, R², and R³ are each, independently, F, Cl, Br, I, H, OH, a methoxy group, an ethoxy group, an isopropoxy group, an alkoxy group, an acetoxy group, a methyl group, an alkyl group, a perfluoroalkyl group, a partially fluorinated alkyl group, a dimethylamino group, a dialkylamino group, an ethylamino group, a monoalkylamino group, an amino group, a phenyl group, or a methoxyethoxyethoxy group.

70. The method of claim 66, wherein the hydrophobic aliphatic group of the second silane comprises at least one of:
an alkyl chain;
a partially fluorinated alkyl chain;
a perfluorinated alkyl chain.

71. The method of claim 66, wherein the silane group of the second silane comprises a group represented by: 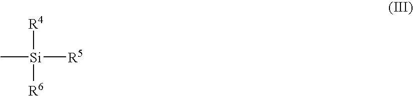
wherein R⁴, R⁵, and R⁶ are each, independently, F, Cl, Br, I, H, OH, a methoxy group, an ethoxy group, an isopropoxy group, an alkoxy group, an acetoxy group, a methyl group, an alkyl group, a perfluoroalkyl group, a partially fluorinated alkyl group, a dimethylamino group, a dialkylamino group, an ethylamino group, a monoalkylamino group, an amino group, a phenyl group, or a methoxyethoxyethoxy group.

72. The method of claim 66, wherein the second silane comprises a structure represented by: 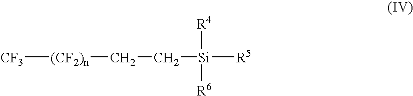
wherein:
n=0 to 32;
R⁴, R⁵, and R⁶ are each, independently, F, Cl, Br, I, H, OH, a methoxy group, an ethoxy group, an isopropoxy group, an alkoxy group, an acetoxy group, a methyl group, an alkyl group, a perfluoroalkyl group, a partially fluorinated alkyl group, a dimethylamino group, a dialkylamino group, an ethylamino group, a monoalkylamino group, an amino group, a phenyl group, or a methoxyethoxyethoxy group.

73. The method of claim 66, further comprising, prior to (a):
(c) oxidizing a portion of the surface.

74. The method of claim 66, wherein the hearing aid device comprises at least one of:
a shell component;
a volume controller;
a battery door;
a microphone cover.

75. The method of claim 66, wherein the hearing aid device comprises a hearing aid accessory, the hearing aid accessory comprising at least one of:
a battery;
a battery contact.

76. A method, comprising:
(a) depositing an adhesion promoting compound onto a surface, the adhesion promoting compound comprising a functional linking group and at least one of:
a silane functional group;
a germanium functional group;
(b) depositing a hydrophobic layer forming compound onto the adhesion promoting compound, the hydrophobic layer forming compound comprising a hydrophobic aliphatic group and at least one of:
a silane functional group;
a germanium functional group.

77. The method of claim 76, wherein the functional linking group of the adhesion promoting compound comprises at least one of:
an isocyanate group;
an acyl halide group;
an epoxide group;
a glycidyl group;
an amino group;
a methyl ester group;
an isothiocyanato group;
a carboxyl group;
an activated carboxyl group;
an alkyl halide group;
a benzyl halide group;
a chlorosilane group;
a methoxysilane group;
an ethoxysilane group.

78. The method of claim 76, wherein the surface comprises a hydroxyl group.

79. The method of claim 78, wherein (a) comprises bonding the adhesion promoting compound to the surface by reacting the functional linking group of the adhesion promoting compound with the hydroxyl group of the surface.

80. The method of claim 76, further comprising, prior to (a):
(c) oxidizing a portion of the surface.

81. The method of claim 76, further comprising, prior to (b):
(d) hydrolyzing the adhesion promoting compound.

82. The method of claim 76, further comprising, prior to (a):
(e) vaporizing the adhesion promoting compound to form a vaporized adhesion promoting compound.

83. The method of claim 76, further comprising, prior to (b):
(f) vaporizing the hydrophobic layer forming compound to form a vaporized hydrophobic layer forming compound.

84. The method of claim 76, further comprising:
(g) cross-linking at least one of:
the adhesion promoting compound;
the hydrophobic layer forming compound.

85. A composition of matter, comprising the reaction product of;
a substrate comprising a hydroxyl group;
an adhesion promoting composition comprising an adhesion promoting compound, the adhesion promoting compound comprising a functional linking group and at least one of:
a silane functional group;
a germanium functional group;
a hydrophobic layer forming composition comprising a hydrophobic layer forming compound, the hydrophobic layer forming compound comprising a hydrophobic aliphatic group and at least one of:
a silane functional group;
a germanium functional group.

86. The composition of matter of claim 85, wherein at least one of the adhesion promoting composition and the hydrophobic layer forming composition comprises a compound having a silane functional group; and
wherein at least one of the adhesion promoting composition and the hydrophobic layer forming composition comprises a compound having a germanium functional group.

87. The composition of matter of claim 85, wherein the functional linking group of the adhesion promoting compound comprises at least one of:
an isocyanate group;
an acyl halide group;
an epoxide group;
a glycidyl group;
an amino group;
a methyl ester group;
an isothiocyanato group;
a carboxyl group;
an activated carboxyl group;
an alkyl halide group;
a benzyl halide group;
a chlorosilane group;
a methoxysilane group;
an ethoxysilane group.

88. The composition of matter of claim 85, wherein the adhesion promoting compound is bonded to the substrate by at least one of:
a carbamate linkage;
an ester linkage;
an ether linkage;
a Si—O—C linkage;
an amide linkage;
an imine linkage;
an ionic linkage;
a siloxane linkage.

89. The composition of matter of claim 85, wherein the adhesion promoting compound comprises a group represented by: 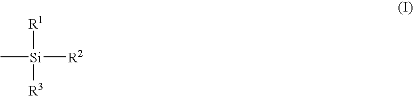
wherein R¹, R², and R³ are each, independently, F, Cl, Br, I, H, OH, a methoxy group, an ethoxy group, an isopropoxy group, an alkoxy group, an acetoxy group, a methyl group, an alkyl group, a perfluoroalkyl group, a partially fluorinated alkyl group, a dimethylamino group, a dialkylamino group, an ethylamino group, a monoalkylamino group, an amino group, a phenyl group, or a methoxyethoxyethoxy group.

90. The composition of matter of claim 85, wherein the adhesion promoting compound comprises a structure represented by: 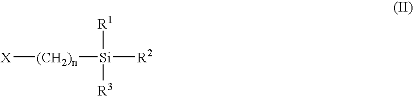
wherein:
n=0 to 32;
X is an isocyanate group, an acyl chloride group, an epoxide group, a glycidyl group, an amino group, a methyl ester group, an isothiocyanato group, a carboxyl group, an activated carboxyl group, an alkyl chloride group, an alkyl bromide group, an alkyl iodide group, a benzyl chloride group, a benzyl bromide group, a chlorosilane group, a methoxysilane group, an ethoxysilane group;
R¹, R², and R³ are each, independently, F, Cl, Br, I, H, OH, a methoxy group, an ethoxy group, an isopropoxy group, an alkoxy group, an acetoxy group, a methyl group, an alkyl group, a perfluoroalkyl group, a partially fluorinated alkyl group, a dimethylamino group, a dialkylamino group, an ethylamino group, a monoalkylamino group, an amino group, a phenyl group, or a methoxyethoxyethoxy group.

91. The composition of matter of claim 85, wherein the hydrophobic aliphatic group of the hydrophobic layer forming compound comprises at least one of:
an alkyl chain;
a partially fluorinated alkyl chain;
a perfluorinated alkyl chain

92. The composition of matter of claim 85, wherein the hydrophobic layer forming compound comprises a group represented by: 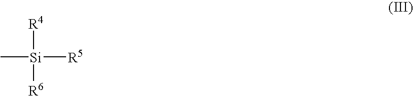
wherein R⁴, R⁵, and R⁶ are each, independently, F, Cl, Br, I, H, OH, a methoxy group, an ethoxy group, an isopropoxy group, an alkoxy group, an acetoxy group, a methyl group, an alkyl group, a perfluoroalkyl group, a partially fluorinated alkyl group, a dimethylamino group, a dialkylamino group, an ethylamino group, a monoalkylamino group, an amino group, a phenyl group, or a methoxyethoxyethoxy group.

93. The composition of matter of claim 85, wherein the hydrophobic layer forming compound comprises a structure represented by: 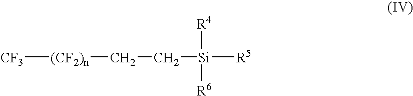
wherein:
n=0 to 32;
R⁴, R⁵, and R⁶ are each, independently, F, Cl, Br, I, H, OH, a methoxy group, an ethoxy group, an isopropoxy group, an alkoxy group, an acetoxy group, a methyl group, an alkyl group, a perfluoroalkyl group, a partially fluorinated alkyl group, a dimethylamino group, a dialkylamino group, an ethylamino group, a monoalkylamino group, an amino group, a phenyl group, or a methoxyethoxyethoxy group.

94. The composition of matter of claim 85, wherein the adhesion promoting compound comprises a group represented by: 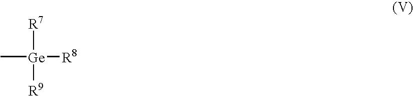
wherein R⁷, R⁸, and R⁹ are each, independently, F, Cl, Br, I, H, OH, a methoxy group, an ethoxy group, an isopropoxy group, an alkoxy group, an acetoxy group, a methyl group, an alkyl group, a perfluoroalkyl group, a partially fluorinated alkyl group, a dimethylamino group, a dialkylamino group, an ethylamino group, a monoalkylamino group, an amino group, a phenyl group, or a methoxyethoxyethoxy group.

95. The composition of matter of claim 85, wherein the adhesion promoting compound comprises a structure represented by: 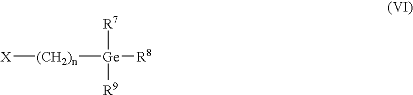
wherein:
n=0 to 32;
X is an isocyanate group, an acyl chloride group, an epoxide group, a glycidyl group, an amino group, a methyl ester group, an isothiocyanato group, a carboxyl group, an activated carboxyl group, an alkyl chloride group, an alkyl bromide group, an alkyl iodide group, a benzyl chloride group, a benzyl bromide group, a chlorosilane group, a methoxysilane group, an ethoxysilane group;
R⁷, R⁸, and R⁹ are each, independently, F, Cl, Br, I, H, OH, a methoxy group, an ethoxy group, an isopropoxy group, an alkoxy group, an acetoxy group, a methyl group, an alkyl group, a perfluoroalkyl group, a partially fluorinated alkyl group, a dimethylamino group, a dialkylamino group, an ethylamino group, a monoalkylamino group, an amino group, a phenyl group, or a methoxyethoxyethoxy group.

96. The composition of matter of claim 85, wherein the hydrophobic layer forming compound comprises a group represented by: 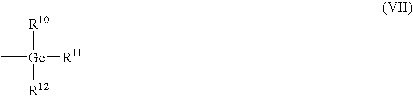
wherein R¹⁰, R¹¹, and R¹² are each, independently, P, Cl, Br, I, H, OH, a methoxy group, an ethoxy group, an isopropoxy group, an alkoxy group, an acetoxy group, a methyl group, an alkyl group, a perfluoroalkyl group, a partially fluorinated alkyl group, a dimethylamino group, a dialkylamino group, an ethylamino group, a monoalkylamino group, an amino group, a phenyl group, or a methoxyethoxyethoxy group.

97. The composition of matter of claim 85, wherein the hydrophobic layer forming compound comprises a structure represented by: 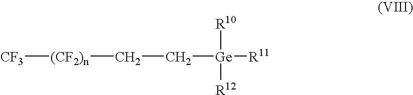
wherein:
n=0 to 32;
R¹⁰, R¹¹, and R¹² are each, independently, F, Cl, Br, I, H, OH, a methoxy group, an ethoxy group, an isopropoxy group, an alkoxy group, an acetoxy group, a methyl group, an alkyl group, a perfluoroalkyl group, a partially fluorinated alkyl group, a dimethylamino group, a dialkylamino group, an ethylamino group, a monoalkylamino group, an amino group, a phenyl group, or a methoxyethoxyethoxy group.

98. The composition of matter of claim 85, wherein the substrate comprises a polymeric substrate.

99. The composition of matter of claim 85, wherein the substrate comprises a silicon based substrate.
